(19) United States
(12) Patent Application Publication
(10) Pub. No.: US 2011/0027542 A1
(43) Pub. Date: Feb. 3, 2011

(54) EXPOSURE APPARATUS AND EXPOSURE METHOD

(75) Inventors: Shinichirou NAGAI, Kanagawa (JP); Shusaku KARUISHI, Kanagawa (JP); Tomonori HARADA, Kanagawa (JP); Hironori KAWASHIMA, Kanagawa (JP); Shinichiro HAYASHI, Kanagawa (JP); Manabu KISHIDA, Kanagawa (JP)

Correspondence Address: SUGHRUE-265550, 2100 PENNSYLVANIA AVE. NW, WASHINGTON, DC, 20037-3213, US

(73) Assignee: NSK Ltd., Tokyo (JP)

(21) Appl. No.: 12/710,396

(22) Filed: Feb. 23, 2010

(30) Foreign Application Priority Data
Jul. 28, 2009 (JP) 2009-175732
Nov. 16, 2009 (JP) 2009-260923
Dec. 7, 2009 (JP) 2009-277719
Jan. 22, 2010 (JP) 2010-012331
Jan. 26, 2010 (JP) 2010-014204
Feb. 2, 2010 (JP) 2010-021412

(51) Int. Cl. G03F 7/20; G03B 27/54; G03B 27/32; B32B 5/00

(52) U.S. Cl. 428/195.1; 430/30; 355/67

(57) ABSTRACT

An exposure method includes the steps of: detecting an alignment mark of a work W and an alignment mark of a mask M by an alignment camera 152; calculating a positional shift amount between the mask M and the work W and a distortion amount of the work W, based on a shift amount between both the alignment marks detected by the alignment camera 152; adjusting an alignment between the work W and the mask M, based on the calculated positional shift amount; and correcting a curvature of a plane mirror 166 for reflecting a light beam of exposure light from a light source 161, based on the calculated distortion amount, at the same timing as the alignment adjustment step or at a different timing from the alignment adjustment step.

This application claims priority from Japanese Patent Applications No. 2009-175732, filed on Jul. 28, 2009, No. 2009-260923, filed on Nov. 16, 2009, No. 2009-277719, filed on Dec. 7, 2009, No. 2010-012331, filed on Jan. 22, 2010, No. 2010-014204, filed on Jan. 26, 2010, and No. 2010-021412, filed on Feb. 2, 2010, the entire contents of which are incorporated by reference herein.

### BACKGROUND OF THE INVENTION

1. Technical Field

The present invention relates to an exposure apparatus and an exposure method, and more particularly to an exposure apparatus and an exposure method wherein a work coated with a photosensitive agent is exposed with exposure light through a mask which is formed with a mask pattern, whereby the mask pattern is transferred onto the work.

2. Related Art

The prior art exposure apparatuses include a proximity exposure apparatus wherein a work coated with a photosensitive agent is held in proximity to a mask with a gap of several tens μm to several hundred μm, and the work is exposed with exposure light through the mask, and a contact exposure apparatus wherein a work is held in close contact with a mask, and the work is exposed with exposure light through the mask (see, e.g., Patent Documents 1 to 3).

With the proximity exposure apparatus described in Patent Document 1, the work in the shape of a hoop or the like is fed into an exposure area by employing a delivery device and a take-up device, and profiling exposure in which the exposure area extending along the conveyance direction of the work is continuously exposed with the exposure light is performed while adjusting the position of the mask so that the position of the mask may coincide with the reference position of the work. Besides, in the proximity exposure apparatus described in Patent Document 2, the mask is arranged in proximity to the work placed on a work stage, and the exposure is performed while making gap adjustments in such a way that the gap between the mask and the work is measured and that the tilt of the work is corrected using a fine vertical motion device which is installed on the work stage.

With the contact exposure apparatus described in Patent Document 3, the work in the shape of a hoop or the like is fed to an exposure position by employing a delivery device and a take-up device, the alignment adjustment between a front mask and a rear mask which have predetermined transfer patterns for the front and rear surfaces of the work, respectively, is made, and the work and the front and rear masks are thereafter brought into close contact. In addition, the exposure light is projected toward the masks, whereby the transfer patterns of the masks are respectively transferred onto the front and rear surfaces of the work by the exposure.

Besides, as the illuminating optical system of the exposure apparatus, there have been contrived various mechanisms wherein, in order to correct the distortion bending aberration of a mirror itself or to cope with the elongation or contraction of the mask or the swell of the work, the curvature of a reflector such as collimation mirror (concave mirror) or plane mirror is locally changed manually (by a feed screw or the like) or automatically (by a piezoelectric transducer or the like) (see e.g., Patent Documents 4 to 8). With, for example, the collimation mirror described in Patent Document 4, the central part of the rear surface of the mirror is fixedly supported, and the individual side parts thereof are movably supported by a bracket. In addition, an alignment mark is observed using a camera for alignment, and the bracket is displaced through a male screw by a motor, whereby the collimation mirror is displaced, and a declination angle is changed every exposure.

Besides, as the mask for use in the exposure apparatuses, it has been contrived to use a film mask which is comparatively inexpensive (see e.g., Patent Documents 9 and 10). In the proximity exposure apparatus described in Patent Document 9, it is described that a transparent glass plate is held by glass-plate holding means, and that the film mask is held by suction on a close-contact plane which is formed at the lower surface of the transparent glass plate, whereby a stable minute gap is ensured for the exposure of high quality. Besides, in the contact exposure apparatus described in Patent Document 10, it is described that the film mask and a supporter are connected at edge parts, and that a fluid is introduced between the film mask and the supporter so as to apply a pressure, whereby the film mask is brought into close contact with the work.

### [The Prior Art Documents]

### [Patent Documents]

Patent Document 1: JP-A-2006-292919

Patent Document 2: JP-A-2002-365810

Patent Document 3: JP-A-2005-92027

Patent Document 4: JP-A-2005-129785

Patent Document 5: JP-A-07-201711

Patent Document 6: JP-A-09-304940

Patent Document 7: JP-A-2001-042281

Patent Document 8: JP-A-2003-077823

Patent Document 9: JP-A-2005-300753

Patent Document 10: Japanese Patent No. 3,099,841

Meanwhile, the hoop-shaped work is shaped into the shape of a flat plate in the exposure area, but it is sometimes distorted at the time of the exposure. Then, a part of the work which is to be exposed to the exposure light does not become rectangular, but it becomes parallelogrammic. In this case, there has been the problem in that, even when the alignment adjustment between the work and the mask is made, a shift appears between the pattern of the mask and the part to-be-exposed of the work, so that an exposure precision lowers.

Besides, the prior-art mechanisms for changing the curvature of the collimation mirror or the plane mirror as described in Patent Documents 4 to 8 are not considered so as to cope with the shape of the area to-be-exposed of the work attributed to the distortion thereof. Moreover, any of these mechanisms has not been capable of sufficiently coping with the shape of the work because of a displacement in a amount in the order of 100 μm.

Further, as the proximity exposure which uses the hoop-shaped work or a sheet-shaped work and which is performed while conveying the work, there is a method wherein the work is exposed with the exposure light with its part to-be-exposed kept stationary in the exposure area, in addition to the profiling exposure as described in Patent Document 1. Also in such an exposure method, it is desired to perform the exposure in a state where the gap between the work and the mask is held uniform. It has been very difficult, however, that the hoop-shaped work, or the sheet-shaped work which is larger than the work stage has its tilt corrected by employing the fine vertical motion device installed on the work stage.

Besides, with the proximity exposure apparatus described in Patent Document 9, the film is drawn on the glass plate by vacuum suction, and hence, a distortion, a wrinkle or the like has been sometimes caused to appear in the film by a suction pressure. Also, in case of using a new film mask, it needs to be drawn by suction anew, and this poses the problem in that a mask replacement time (apparatus down time) becomes long. Further, with the contact exposure apparatus described in Patent Document 10, the operation of releasing the connections is required in replacing the film mask, and a mask replacement time (apparatus down time) becomes long. Still further, both the apparatuses require mechanisms each of which draws the film mask onto the glass plate by suction, and they have had the problem of complicated apparatuses.

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any of the problems described above.

Accordingly, an object of the present invention is to provide an exposure apparatus and an exposure method in which, even when a work is distorted, the pattern of a mask can be precisely transferred by exposure in correspondence with the shape of the exposed area of the work. Another object is to provide a proximity exposure apparatus and a proximity exposure method in which, in conveying a work to an exposure area and exposing the work with exposure light while the work is kept stationary in the exposure area, the exposure can be performed after a tilt correction for uniformalizing the gap between the work and a mask, and an exposure precision can be enhanced.

According to one or more aspects of the present invention, there is provided an exposure method in which a light beam of exposure light from a light source is projected onto a work through a mask, and a pattern of the mask is transferred onto the work. The method comprises the steps of: detecting an alignment mark of the work and an alignment mark of the mask by an alignment detection system; calculating a positional shift amount between the mask and the work and a distortion amount of the work, based on a shift amount between both of the alignment marks detected by the alignment detection system; adjusting an alignment between the work and the mask, based on the calculated positional shift amount; and correcting a curvature of a reflector, which reflects the light beam of the exposure light from the light source, based on the calculated distortion amount at the same timing as the alignment adjustment step or at a different timing from the alignment adjustment step.

According to one or more aspects of the present invention, there is provided an exposure apparatus comprising: a work support which supports a work; a mask support which supports a mask; a feed mechanism which relatively moves the work and the mask; an illuminating optical system which comprises a light source and a reflector for reflecting a light beam of exposure light from the light source; and an alignment detection system which detects an alignment mark of the work and an alignment mark of the mask, wherein the light beam of the exposure light from the light source is projected onto the work through the mask, so as to transfer the pattern of the mask onto the work. The illuminating optical system comprises: a support mechanism which supports either of a peripheral edge portion of the reflector or a rear surface of the reflector; and a support mechanism drive unit capable of moving the support mechanism. The feed mechanism relatively moves the work and the mask based on a positional shift amount between the mask and the work so as to adjust an alignment between the work and the mask, wherein the positional shift amount is calculated from a shift amount between both of the alignment marks, the shift amount being detected by the alignment detection system. The curvature of the reflector is corrected such that the support mechanism drive unit moves the support mechanism based on a distortion amount of the work, which is calculated from the shift amount between both of the alignment marks, the shift amount being detected by the alignment detection system.

According to one or more aspects of the present invention, there is provided a proximity exposure apparatus comprising: a mask holder which holds a mask; a conveyance mechanism which conveys a work to an exposure area opposite to the mask; and an illuminating optical system which projects exposure light onto the work located in the exposure area, through the mask, wherein a light beam of the exposure light from the illuminating optical system is projected onto the work through the mask in a state where an exposed portion of the work conveyed to the exposure area is kept stationary and a gap between the work and the mask is close to a predetermined gap, thereby to transfer a pattern of the mask onto the work; at least two alignment detection systems each of which detects an alignment mark of the work and an alignment mark of the mask; at least three gap detection systems each of which detects the gap between the work and the mask located in the exposure area; and a mask drive mechanism capable of driving the mask holder in an X-direction and a Y-direction orthogonal to each other on a horizontal plane, and a θ-direction round an axis orthogonal to the horizontal plane, and capable of tilt-driving the mask holder. The mask drive mechanism adjusts an alignment between the work and the mask by driving the mask holder on the horizontal plane based on the shift amount between both the alignment marks, which is detected by the alignment detection system, and the mask drive mechanism corrects a relative inclination between the work and the mask by tilt-driving the mask holder based on the gap detected by the gap detection system.

According to one or more aspects of the present invention, there is provided a proximity exposure method using a proximity exposure apparatus, the proximity exposure apparatus including: a mask holder that holds a mask; a conveyance mechanism that conveys a work to an exposure area opposite to the mask; an illuminating optical system that projects exposure light onto the work located in the exposure area, through the mask; at least two alignment detection systems each detecting an alignment mark of the work and an alignment mark of the mask; at least three gap detection systems each detecting a gap between the work and the mask located in the exposure area; and a mask drive mechanism capable of driving the mask holder in an X-direction and a Y-direction orthogonal to each other on a horizontal plane, and a θ-direction round an axis orthogonal to the horizontal plane, and capable of tilt-driving the mask holder, wherein a light beam of the exposure light from the illuminating optical system is projected onto the work through the mask in a state where an exposed portion of the conveyed work is kept stationary and the gap between the work and the mask is close to a predetermined gap, thereby to transfer a pattern of the mask onto the work, the method comprising the steps of: detecting the alignment mark of the work and the alignment mark of the mask with the alignment detection systems; adjusting an alignment between the work and the mask by driving the mask holder on the horizontal plane by the mask drive mechanism, based on a shift amount between both of the alignment marks, the shift amount being detected by the alignment detection systems; and correcting a relative inclination between the work and the mask by tilt-driving the mask holder by the mask drive mechanism, based on the gap detected by the gap detection system.

According to the exposure method and exposure apparatus of the present invention, the positional shift amount between a mask and a work and the distortion amount of the work are calculated based on the shift amount between the alignment marks of the work and the mask, which are detected by an alignment detection system, the alignment between the work and the mask is adjusted based on the calculated positional shift amount, and the curvature of the reflector which reflects the light beam of exposure lights from light sources is corrected based on the calculated distortion amount, at the same timing as the alignment adjustment or at a different timing from the alignment adjustment. Accordingly, even in a case where the work is distorted, the pattern of the mask can be precisely transferred by exposure in conformity with the shape of the exposed area of the work.

Besides, in the reflector curvature correction, light having a directivity is projected toward the reflector from an exposure surface side with respect to the reflector, the light having the directivity reflected on a reflection plate is imaged by an imaging device through the reflector, the displacement amount of the light having the directivity, which is imaged in correcting the curvature of the reflector, is detected, and the curvature is corrected such that the displacement amount corresponds to the calculated distortion amount, whereby the reflector curvature correction corresponding to the distortion amount of the work can be reliably made while imaging the displacement amount of the light having the directivity.

According to the proximity exposure apparatus of the present invention, in a state where the exposed portion of the work conveyed into an exposure area is kept stationary and the gap between the work and the mask are close to a predetermined gap, the light beam of the exposure light from an illuminating optical system is projected onto the work through the mask, thereby to transfer the pattern of the mask onto the work. Here, the proximity exposure apparatus includes at least two alignment detection systems which detect the alignment mark of the work and the alignment mark of the mask, respectively, at least three gap detection systems which detect the gaps between the work and the mask located in the exposure area, respectively, and a mask drive mechanism which can drive a mask holder in an X-direction and a Y-direction orthogonal to each other on a horizontal plane and can tilt-drive the mask holder in a θ-direction round an axis orthogonal to the horizontal plane. The mask drive mechanism adjusts the alignment between the work and the mask by driving the mask holder on the horizontal plane, based on the shift amount between both the alignment marks, which is detected by the alignment detection systems, and the mask drive mechanism corrects the relative inclination between the work and the mask, by tilt-driving the mask holder based on the gaps detected by the gap detection systems. Accordingly, in conveying the work and exposing the work with the exposure light in the stationary state in the exposure area, the exposure can be performed after the alignment adjustment, and the tilt correction for uniformalizing the gap between the work and the mask. Thus, the pattern of the mask can be precisely transferred by the exposure.

Besides, according to the proximity exposure method of the present invention, in the state where the exposed portion of the conveyed work is kept stationary in the exposure area and where the gap between the work and the mask are close to the predetermined gap, the light beam of the exposure light from the illuminating optical system is projected onto the work through the mask, thereby to transfer the pattern of the mask onto the work. Here, the proximity exposure method includes the step of detecting the alignment mark of the work and the alignment mark of the mask using the alignment detection system, the step of adjusting the alignment between the work and the mask by driving the mask holder on the horizontal plane with the mask drive mechanism, based on the shift amount between both of the alignment marks detected by the alignment detection system, and the step of correcting the relative inclination between the work and the mask by tilt-driving the mask holder with the mask drive mechanism, based on the gap detected by the gap detection system. Accordingly, in conveying the work and exposing the work with the exposure light in the state where it is stationary in the exposure area, the exposure can be performed after the alignment adjustment and the tilt correction for uniformalizing the gap between the work and the mask, and the pattern of the mask can be precisely transferred by the exposure.

Other aspects of the invention will be apparent from the following description, the drawings and the claims.

### BRIEF DESCRIPTION OF THE DRAWINGS

FIG. 1 is a schematic view for explaining a proximity exposure apparatus according to the first embodiment of the present invention;

FIG. 2 is a perspective view of a mask holding mechanism in FIG. 1;

FIG. 3 is a plan view of the mask holding mechanism in FIG. 1;

FIG. 4 is a sectional view taken along IV-IV in FIG. 3;

FIG. 5 is an enlarged view of a first drive mechanism in FIG. 4;

FIG. 6 is a sectional view taken along VI-VI in FIG. 3;

FIG. 7 is a vertical sectional view of a mask holding mechanism in a modified embodiment;

FIG. 8A is a sectional view showing the details of a mask in a modified embodiment, and FIG. 8B shows another modified embodiment;

FIG. 9A is a front view showing an alignment detection system and a sensor carrier on which gap sensors are mounted, and FIG. 9B is a corresponding side view;

FIG. 10 is a view showing a modified embodiment of the sensor carrier;

FIG. 11 is a view showing an illuminating optical system and a curvature-correction-amount detection system in FIG. 1;

FIG. 12A is a front view showing a cassette, FIG. 12B is a sectional view of the cassette as seen in a direction XII in FIG. 12A, and FIG. 12C is a view showing a sectional view of the cassette as seen in a direction XII′ in FIG. 12A, together with an integrator lens;

FIG. 13 is an enlarged sectional view of the vicinity of a light source which is mounted in the cassette;

FIG. 14 is a view for showing the control configurations of the individual light sources;

FIG. 15 is a sectional view of the cassette showing a modified embodiment of a lamp keeper mechanism;

FIG. 16A is a front view showing the reflector support structure of the illuminating optical system, FIG. 16B is a sectional view taken along line XVI-XVI in FIG. 16A, and FIG. 16C is a sectional view taken along line XVI′-XVI′ in FIG. 16A;

FIG. 17 is a view showing a state where the support mechanism of the reflector support structure in FIGS. 16A to 16C has been operated;

FIG. 18 is a view showing a modified embodiment of the reflector support structure of the illuminating optical system;

FIG. 19 is a diagram showing a flow chart of an exposure method in this embodiment;

FIG. 20 is a view showing the positional relation between the mask and a work after an alignment adjustment;

FIG. 21A is a view showing a state before the curvature of a reflector is corrected, FIG. 21B is an imaging diagram of a left camera in FIG. 21A, and FIG. 21C is an imaging diagram of a right camera in FIG. 21A:

FIG. 22A is a view showing a state after the curvature of the reflector has been corrected, FIG. 22B is an imaging diagram of a left camera in FIG. 22A, and FIG. 22C is an imaging diagram of a right camera in FIG. 22A.

FIG. 23 is a diagram showing the displacement amounts of laser lights projected on a reflection plate;

FIG. 24 is a perspective view of a mask holding mechanism according to the second embodiment of the present invention;

FIG. 25A is a view showing a state before the curvature of a reflector is corrected, in an exposure apparatus according to the second embodiment of the present invention, FIG. 25B is an imaging diagram of a left camera in FIG. 25A, and FIG. 25C is an imaging diagram of a right camera in FIG. 25A;

FIG. 26A is a view showing a state after the curvature of the reflector has been corrected, in the exposure apparatus in FIGS. 25A to 25C, FIG. 26B is an imaging diagram of the left camera in FIG. 26A, and FIG. 26C is an imaging diagram of the right camera in FIG. 26A;

FIG. 27 is a view showing a curvature-correction-amount detection system according to the fourth embodiment of the present invention;

FIG. 28 is a schematic view for explaining a both-sided exposure apparatus according to the fifth embodiment of the present invention;

FIG. 29 is a sectional view showing a mask support mechanism in FIG. 28;

FIGS. 30A to 30D are views showing an alignment mechanism, in which FIG. 30A is a front view, FIG. 30B is a sectional view along XXX-XXX in FIG. 30A, FIG. 30C is a sectional view along XXX′-XXX′ in FIG. 30A, and FIG. 30D is a sectional view along XXX″-XXX″ in FIG. 30B;

FIG. 31 is a sectional view showing the details of a film mask which is applied to the fifth embodiment;

FIG. 32 is a view for explaining a state where the curvature of a reflector is corrected using the film mask in the fifth embodiment; and

FIG. 33 is a view for explaining a state where the curvature of the reflector is corrected using a mask to which a transparent medium is attached, in the fifth embodiment.

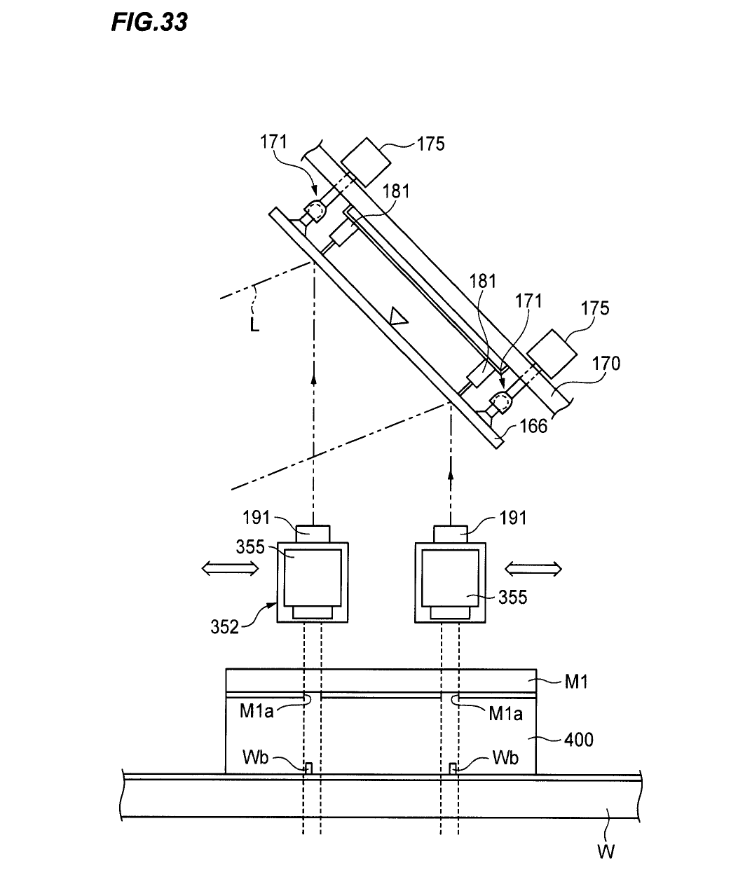

### DETAILED DESCRIPTION OF EXEMPLARY EMBODIMENTS

Now, a proximity exposure apparatus and a proximity exposure method according to the individual embodiments of the present invention will be described in detail with reference to the drawings. In the embodiments, the conveyance direction of a work shall be defined as an X-direction being one direction on a horizontal plane, that direction on the horizontal plane which is orthogonal to the X-direction shall be defined as a Y-direction, a perpendicular direction which is orthogonal to the X-direction and the Y-direction shall be defined as a Z-direction, and a direction which is round an axis orthogonal to the X-direction and the Y-direction shall be defined as a θ-direction.

### First Embodiment

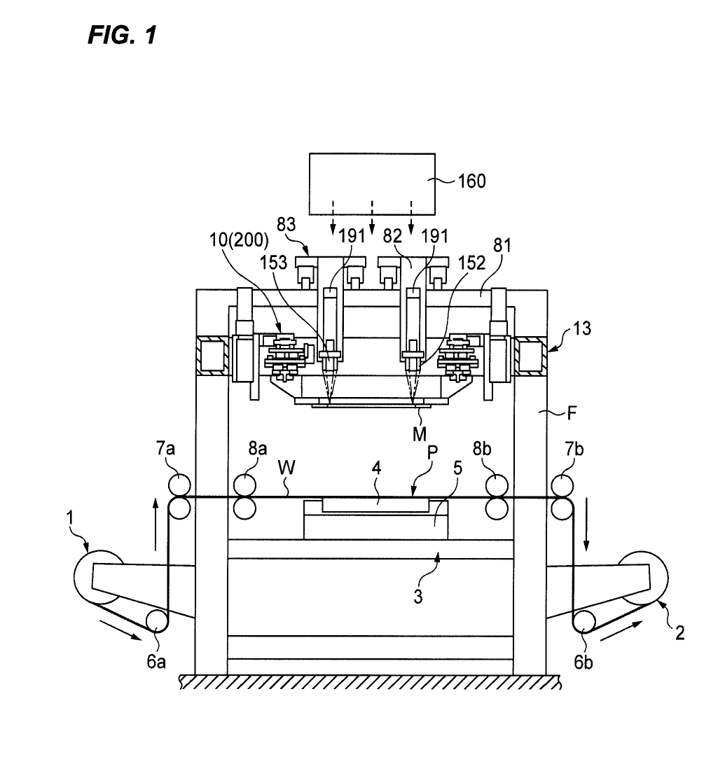

First, the proximity exposure apparatus of the first embodiment will be described with reference to FIG. 1. Referring to the figure, numeral 1 designates a delivery device which delivers a work W, such as hoop material, by tact feed in a horizontal direction. Numeral 2 designates a take-up device which is arranged on the downstream side of an exposure area P and which takes up the work W subjected to exposure.

A trestle 3 which extends along the conveyance direction of the work W is disposed between the delivery device 1 and the take-up device 2 in a manner to be spanned between a plurality of erect frames F. A work table (work support) 5, which includes a work chuck 4 for drawing the work W by suction and on which the work W is supported, is disposed on the trestle 3, and the exposure area P is formed at the position of the work chuck 4. Besides, tension rolls 6a and 6b, pairs of guide rolls 7a and 7b, and pairs of index rolls 8a and 8b are respectively arranged between the delivery device 1 and the exposure area P, and between the take-up device 2 and the exposure area P.

The tension rolls 6a and 6b are mounted so as to be drivable in the Z-direction, and they prevent the sag of the work W. The pairs of guide rolls 7a and 7b are mounted so as to be drivable in the X-direction, and they hold the work W therebetween so as to apply a tension to the work W located in the exposure area P. The pairs of index rolls 8a and 8b are mounted so as to be drivable in the Y-direction and the θ-direction, and they move the work W so as to adjust the positions of the work W and a mask M. In this embodiment, the delivery device 1, the take-up device 2, the tension rolls 6a and 6b, the pairs of guide rolls 7a and 7b, and the pairs of index rolls 8a and 8b constitute the conveyance device of the present invention.

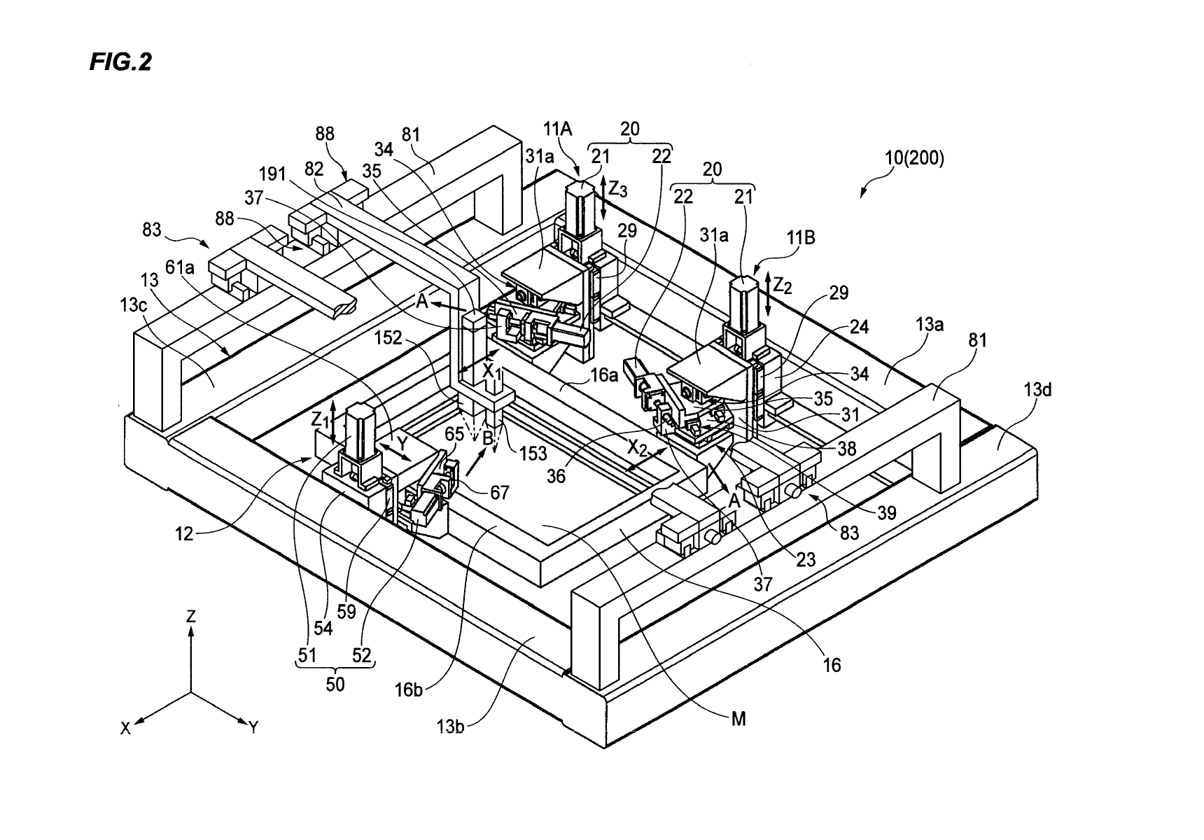

As shown in FIG. 2 to FIG. 6, a mask holding mechanism 10 includes a substantially rectangular, mask holder 16 which holds the mask M, and a pair of first drive mechanisms 11A and 11B and a second drive mechanism 12 which constitute the mask drive mechanism 200 of the present invention. The pair of first drive mechanisms 11A and 11B and the second drive mechanism 12 are disposed in a substantially rectangular border-like frame 13 which is fixed to the erect frame F of the proximity exposure apparatus. The pair of first drive mechanisms 11A and 11B are fixed to one side 13a of the mask holder 16 extending in the Y-direction, in a manner to be spaced in the Y-direction, and they support one side 16a of the mask holder 16 extending in the Y-direction, at positions distant equal intervals from the intermediate position of the side 16a, respectively. The second drive mechanism 12 is fixed to the other side 13b of the frame 13 extending in the Y-direction, and it supports the intermediate position of one side 16b of the mask holder 16 opposing to the side 16a supported by the pair of first drive mechanisms 11A and 11B.

The first and second drive mechanisms 11A, 11B and 12 hold the mask holder 16 which holds the mask M at its lower surface, so as to be movable in the X-, Y-, Z- and θ-directions within the border of the frame 13. Incidentally, the pair of first drive mechanisms 11A and 11B have an identical structure except that the mounting directions of X-axis motors 22 to be described later are different from each other. In the ensuing description, therefore, the first drive mechanism 11A will be chiefly explained.

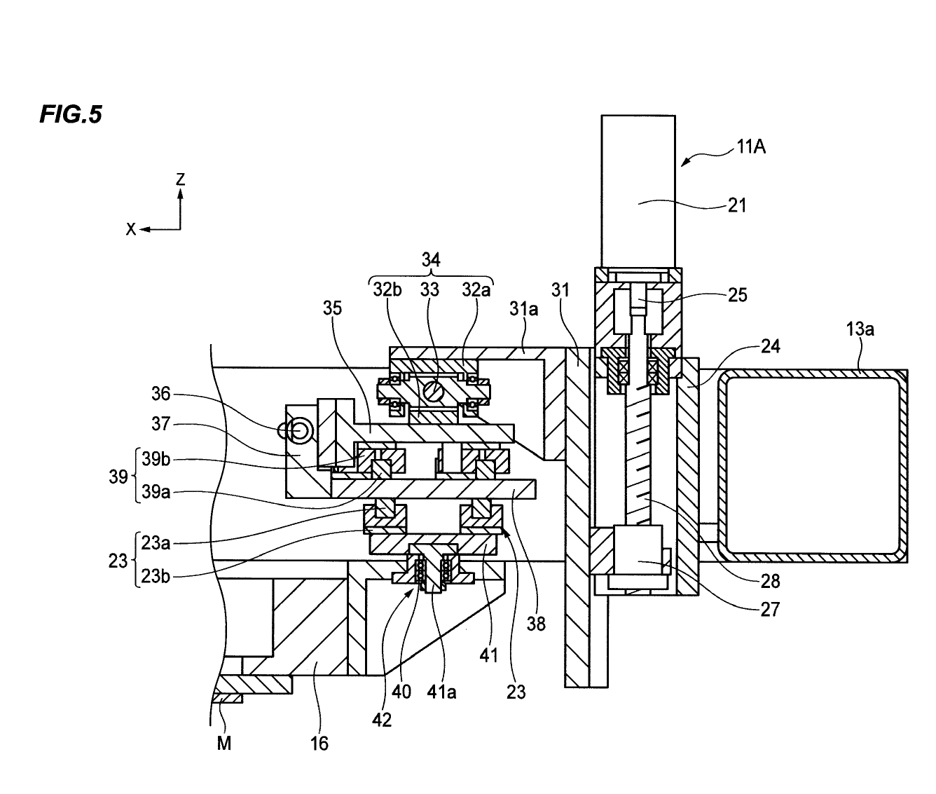

Referring also to FIG. 5, the first drive mechanism 11A includes a first drive portion 20 which has a first Z-axis motor 21 capable of driving the mask holder 16 in the Z-direction and the X-axis motor 22 capable of driving the mask holder 16 in the X-direction, and a pair of Y-directional linear guides 23 which are a first guide for guiding the mask holder 16 in the Y-direction. The first Z-axis motor 21 has a rotary shaft 25 fixed downwards in the Z-direction, to a housing 24 fixed to one side 13a of the frame 13. A screw shaft 28 which is rotatably supported by the housing 24 is connected to the rotary shaft 25, and it configures a ball screw mechanism together with a nut 27 which is in threadable engagement with the screw shaft 28.

A first Z-axial movable base 31 which is movable in the Z-direction when guided by a linear guide 29 in the Z-axial direction is fixed to the nut 27. Thus, when the first Z-axis motor 21 is rotated, the first Z-axial movable base 31 is moved in the Z-direction.

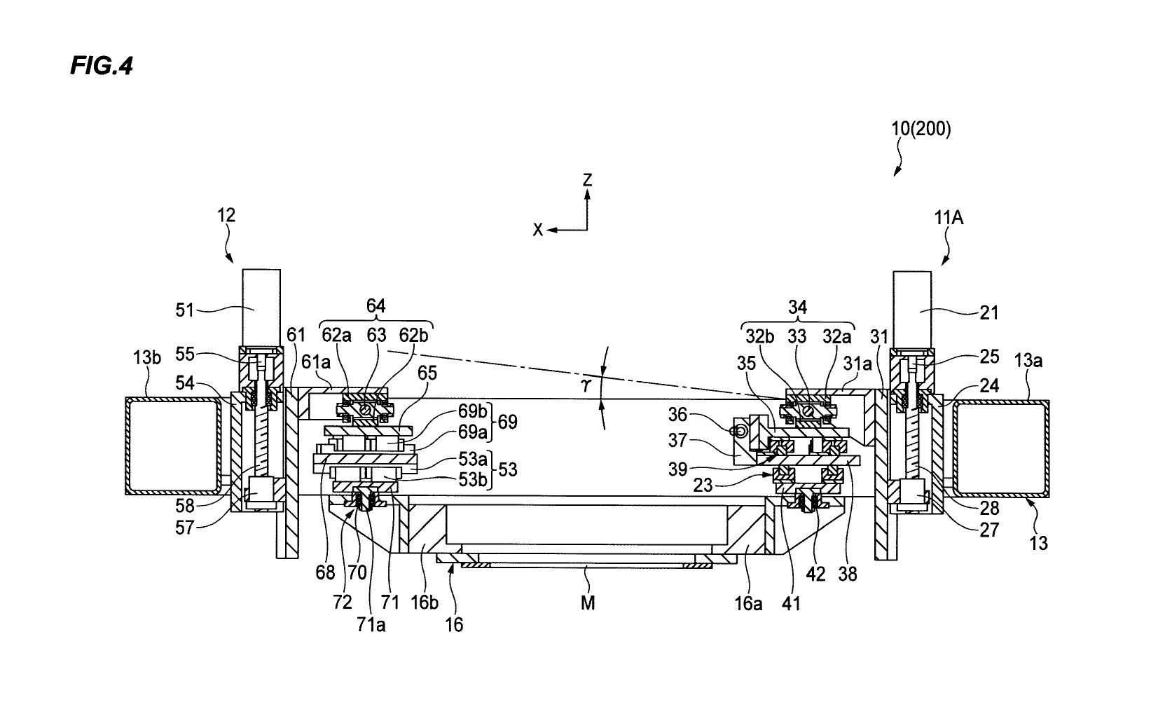

One U-shaped member 32a of a cross joint 34 serving as a first universal joint is fixed to an overhang portion 31a which is formed so as to spread out from the upper part of the first Z-axial movable base 31 toward the inner side of the frame 13 (in the X-direction). The cross joint 34 is configured of one pair of U-shaped members 32a and 32b as which bearing portions provided at both the ends of this cross joint are arranged by being combined in directions orthogonal to each other, and cross shafts 33 which are turnably fitted in the corresponding bearing portions. Thus, the other U-shaped member 32b is connected to one U-shaped member 32a so as to be rotatable within an X-Z plane and a Y-Z plane. By the way, in FIG. 4, the cross joint 34, and a cross joint 64 etc. to be described later are schematically shown.

The other U-shaped member 32b of the cross joint 34 is fixed to an X-axis motor base 35. The X-axis motor 22 is fixed to the X-axis motor base 35 so as to be inclined a predetermined angle α in a first inclination direction, that is, relative to the X-direction within a horizontal plane (X-Y plane) (see FIG. 4). A nut 37 is in threadable engagement with a screw shaft 36 fixed to the rotary shaft of the X-axis motor 22, and this nut 37 is fixed to a first guide plate 38. Incidentally, the respective X-axis motors 22 of the pair of first drive mechanisms 11A and 11B have the mounting angles α of their axes arranged in line symmetry with respect to the X-directional center line X between the pair of first drive mechanisms 11A and 11B (in this embodiment, the X-directional center line passing through the center of gravity G of the mask holder 16).

A pair of linear guides 39 serving as a third guide, each of which consists of a guide rail 39a and a slider 39b, are disposed between the upper surface of the first guide plate 38 and the lower surface of the X-axis motor base 35 in a manner to be parallel to the axis of the screw shaft 36, and they guide the first guide plate 38 in the first inclination direction.

Besides, the pair of linear guides 23 serving as the first guide, each of which consists of a guide rail 23a and a slider 23b extending in the Y-direction, are disposed under the first guide plate 38, and they guide in the Y-direction a rotary base 41 which is fixed to the pair of sliders 23b. A rotary shaft 41a is mounted on the rotary base 41, and a ball-and-roller bearing 40 is arranged round the rotary shaft 41a, thereby to configure a rotary support mechanism 42 which supports the mask holder 16 so as to be rotatable within the horizontal plane.

The second drive mechanism 12 includes a second drive portion 50 which has a second Z-axis motor 51 capable of driving the mask holder 16 in the Z-direction, and a Y-axis motor 52 capable of driving the portion 16 in the Y-direction, and an X-directional linear guide 53 which is a second guide for guiding the mask holder 16 in the X-direction.

The second Z-axis motor 51 is fixed to a housing 54 which is fixed to one side 13b of the frame 13, with its rotary shaft 55 held downward in the Z-direction. A screw shaft 58 which is rotatably supported by the housing 54, is connected to the rotary shaft 55, and it configures a ball screw mechanism together with a nut 57 which is in threadable engagement with the screw shaft 58.

A second Z-axial movable base 61 which is made movable in the Z-direction when guided by a linear guide 59 in the Z-axial direction is fixed to the nut 57. Thus, when the second Z-axis motor 51 is rotated, the second Z-axial movable base 61 is moved in the Z-direction.

One U-shaped member 62a of a cross joint 64 serving as a second universal joint is fixed to an overhang portion 61a which is formed so as to spread out from the upper part of the second Z-axial movable base 61 toward the inner side of the frame 13 (in the X-direction). The cross joint 64 is configured of one pair of U-shaped members 62a and 62b as which bearing portions provided at both the ends of this cross joint are arranged by being combined in directions orthogonal to each other, and cross shafts 63 which are turnably fitted in the corresponding bearing portions. Thus, the other U-shaped member 62b is connected to one U-shaped member 62a so as to be rotatable within the X-Z plane and the Y-Z plane.

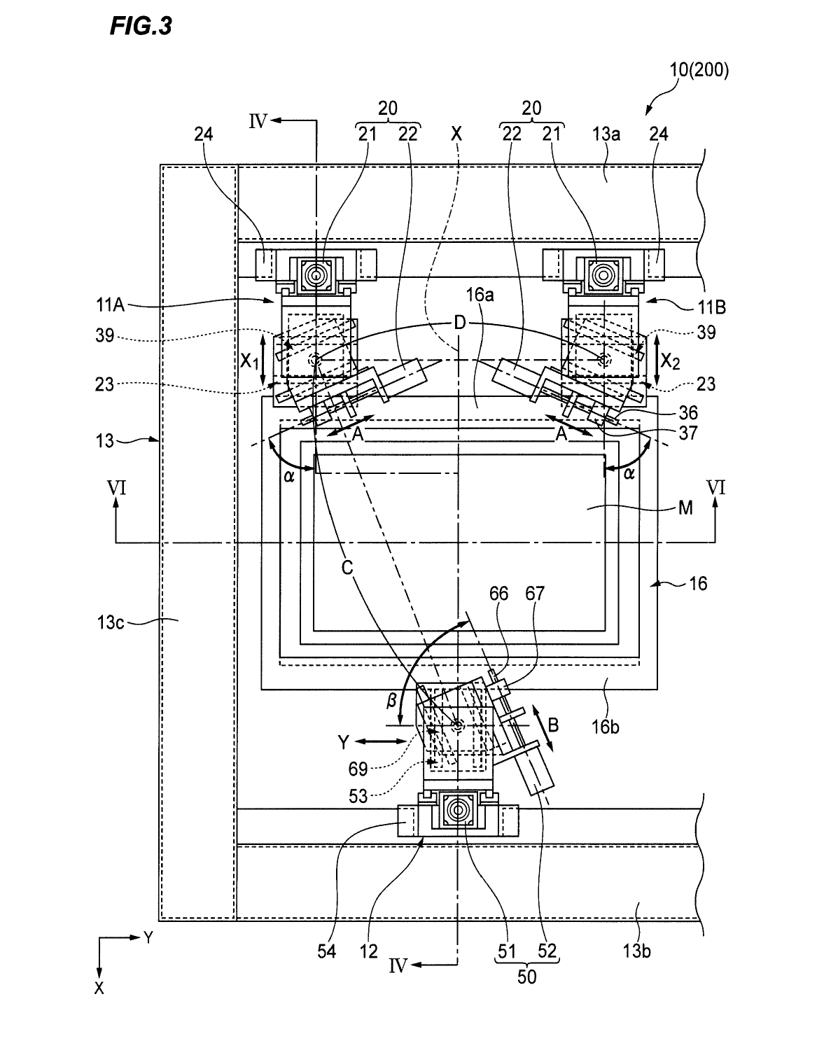

The other U-shaped member 62b of the cross joint 64 is fixed to a Y-axis motor base 65. The Y-axis motor 52 is fixed to the Y-axis motor base 65 so as to be inclined a predetermined angle β in a second inclination direction, that is, relative to the Y-direction within the horizontal plane (X-Y plane) (see FIG. 3). A nut 67 is in threadable engagement with a screw shaft 66 fixed to the rotary shaft of the Y-axis motor 52, and this nut 67 is fixed to a second guide plate 68.

A pair of linear guides 69 serving as a fourth guide, each of which consists of a guide rail 69a and a slider 69b, are disposed between the upper surface of the second guide plate 68 and the lower surface of the Y-axis motor base 65 in a manner to be parallel to the axis of the screw shaft 66, and they guide the second guide plate 68 in the second inclination direction.

Besides, the pair of linear guides 53 serving as the second guide, each of which consists of a guide rail 53a′ and a slider 53b′ extending in the X-direction, are disposed under the second guide plate 68, and they guide in the X-direction a rotary base 71 which is fixed to the pair of sliders 53b′. A rotary shaft 71a is mounted on the rotary base 71, and a ball-and-roller bearing 70 is arranged round the rotary shaft 71a, thereby to configure a rotary support mechanism 72 which supports the mask holder 16 so as to be rotatable within the horizontal plane.

As described above, the mask holder 16 is supported on the Z-axial movable bases 31, 31 and 61 through the three cross joints 34, 34 and 64. Therefore, the relative inclinations between the Z-axial movable bases 31, 31 and 61 (frame 13) and the mask holder 16 generated when any of the first Z-axis motors 21 and 21 of the pair of first drive mechanisms 11A and 11B and the second Z-axis motor 51 of the second drive mechanism 12 has operated is absorbed by the rotation of the three cross joints 34, 34 and 64.

Besides, the mask holder 16 is supported on the Z-axial movable bases 31, 31 arid 61 through the ball-and-roller bearings 40 and 40 of the pair of first drive mechanisms 11A and 11B and the ball-and-roller bearing 70 of the second drive mechanism 12. Therefore, the relative rotation (rotation round a Z-axis) θ between the frame 13 and the mask holder 16 generated when any of the X-axis motors 22 and 22 of the pair of first drive mechanisms 11A and 11B and the Y-axis motor 52 of the second drive mechanism 12 has operated is absorbed by the three ball-and-roller bearings 40, 40 and 70.

Now, the individual operations of the mask holding mechanism 10 in this embodiment will be described.

(X-Directional Movement)

The X-directional movement of the mask holder 16 is performed in such a way that the X-axis motors 22 and 22 of the pair of first drive mechanisms 11A and 11B are synchronously rotated in directions reverse to each other. As shown in FIGS. 2 and 3, the two X-axis motors 22 and 22 are rotated, whereby the first guide plate 38 is moved in the first inclination direction (direction of an arrow A) while being guided by the pair of linear guides 39 of the X-axis motor base 35 through the nut 37 which is in threadable engagement with the screw shaft 36.

Since the pair of linear guides 39 incline the angle α with respect to an X-axis, the Y-directional component of the moving distance of the first guide plate 38 in the first inclination direction (first-inclination-direction moving distance of the first guide plate 38×sin α) is absorbed by the relative movement between the guide rail 23a and slider 23b of the first guide 23. Accordingly, the rotary base 41, that is, the mask holder 16 does not move in the Y-direction.

On the other hand, the X-directional component of the moving distance of the first guide plate 38 in the first inclination direction (first-inclination-direction moving distance of the first guide plate 38×cos α) is orthogonal to the guide direction (Y-direction) of the first guide 23, so that the X-directional component of the moving distance is transmitted to the mask holder 16 through the rotary base 41, to move the mask holder 16 in the X-direction. On this occasion, the second guide 53 of the second drive mechanism 12 allows the X-directional movement of the mask holder 16 owing to the relative movement between the guide rail 53a′ and the slider 53b′

As described above, the mask holder 16 is horizontally moved in the X-direction without rotating (in the θ direction), by synchronously rotating the X-axis motors 22 and 22 of the pair of first drive mechanisms 11A and 11B so that the X-directional components of the moving distances of the two first guide plates 38 and 38 in the first inclination direction may become the same lengths.

Besides, since the pair of linear guides 39 incline the angle α with respect to the X-axis, the cos α of the moving distance of the first guide plate 38 in the first inclination direction becomes the X-directional moving distance of the mask holder 16. This is smaller than the first-inclination-direction moving distance of the first guide plate 38. That is, the large moving distance of the first guide plate 38 in the first inclination direction is converted into the small X-directional moving distance of the mask holder 16. Accordingly, the first guide plate 38 is driven in a direction inclined the angle α with respect to the X-axis, whereby the first guide 23 acts as a displacement reduction mechanism. Thus, it is possible to control the X-directional movement of the mask holder 16 at high precision.

(θ-Directional Rotation)

The θ-directional rotation of the mask holder 16 is performed by rotating the X-axis motors 22 and 22 of the pair of first drive mechanisms 11A and 11B at different rotation numbers. As shown in FIGS. 3 and 4, when the rotation number of the X-axis motor 22 of the first drive mechanism 11A is higher than that of the X-axis motor 22 of the first drive mechanism 11B by way of example, the X-directional moving distance (X1) of the rotary base 41 of the first drive mechanism 11A becomes larger than the X-directional moving distance (X2) of the rotary base 41 of the first drive mechanism 11B, and the mask holder 16 is turned in the counterclockwise direction. Besides, when the rotation number of the X-axis motor 22 of the first drive mechanism 11A is lower than that of the X-axis motor 22 of the first drive mechanism 11B, the mask holder 16 is turned in the clockwise direction.

On this occasion, the relative rotations (θ) between the mask holder 16, and the pair of first drive mechanisms 11A and 11B and the second drive mechanism 12 which are fixed to the frame 13 are absorbed by the rotary support mechanisms 42, 42 and 72 which are arranged at the joined parts between the rotary bases 41, 41 and 71 and the mask holder 16. Besides, the mask holder 16 is sometimes moved in the X- and Y-directions relatively to the frame 13 by the θ-directional rotations of the mask holder 16 (the mask holder 16 is moved in the X- and Y-directions while rotating in the θ-direction), and the X- and Y-directional movements are absorbed by the first guide 23 and the second guide 53.

(Y-Directional Movement)

The Y-directional movement of the mask holder 16 is performed by rotating the Y-axis motor 52 of the second drive mechanism 12. As shown in FIGS. 3 and 4, the Y-axis motor 52 is rotated, whereby the second guide plate 68 is moved in the second inclination direction (the direction of an arrow B) while being guided by the fourth guide 69 of the Y-axis motor base 65, through the nut 67 held in engagement with the screw shaft 66.

Since the fourth guide 69 is inclined the angle β with respect to the Y-axis, the X-directional component of the moving distance of the second guide plate 68 in the second inclination direction (second-inclination-direction moving distance of the second guide plate 68×sin β) is absorbed by the relative movement between the guide rail 53a′ and slider 53b′ of the linear guide 53. Accordingly, the rotary base 71, that is, the mask holder 16 is not moved in the X-direction.

On the other hand, the Y-directional component of the moving distance of the second guide plate 68 in the second inclination direction (second-inclination-direction moving distance of the second guide plate 68×cos β) is orthogonal to the guide direction (X-direction) of the second guide 53, so that it is transmitted to the mask holder 16 through the rotary base 71, to move the mask holder 16 in the Y-direction. On this occasion, the pair of linear guides 23 of the pair of first drive mechanisms 11A and 11B allow the Y-directional movement of the mask holder 16 owing to the relative movement between the guide rail 23a and the slider 23b.

Besides, since the fourth guide 69 inclines the angle β with respect to the Y-axis, the cos β of the moving distance of the second guide plate 68 in the second inclination direction becomes the Y-directional moving distance of the mask holder 16. This is smaller than the second-inclination-direction moving distance of the second guide plate 68. That is, the large moving distance of the second guide plate 68 in the second inclination direction is converted into the small Y-directional moving distance of the mask holder 16. Accordingly, the second guide plate 68 is driven in a direction inclined the angle β with respect to the Y-axis, whereby the second guide 53 acts as a displacement reduction mechanism. Thus, it is possible to control the Y-directional movement of the mask holder 16 at high precision.

(Z-Directional Movement)

The Z-directional movement of the mask holder 16 is performed by rotating the first Z-axis motors 21 and 21 of the pair of first drive mechanisms 11A and 11B and the second Z-axis motor 51 of the second drive mechanism 12. As shown in FIG. 5, the first Z-axis motors 21 and 21 and the second Z-axis motor 51 are rotated, whereby the first Z-axial movable bases 31 and 31 and the second Z-axial movable base 61 are moved in the Z-direction through the nuts 27, 27 and 57 which are in threadable engagement with the screw shafts 28, 28 and 58. The Z-directional movements are transmitted to the mask holder 16 through the cross joints 34, 34 and 64, the pair of linear guides 23 and 23 serving as the first guide, the pair of linear guides 53 serving as the second guide, and the rotary support mechanisms 42 and 72, and the mask holder 16 is moved in the Z-direction.

(Movement Between Operation Position and Retreat Position of Mask)

The rotation numbers of the first Z-axis motors 21 and 21 and the second Z-axis motor 51 are increased, whereby the mask holder 16 is largely moved in the Z-direction, and it is possible to move between an operation position proximate to the work W and a retreat position distant from the work W. On this occasion, the first Z-axis motors 21 and 21 and the second Z-axis motor 51 are synchronously rotated, whereby the mask holder 16 can be largely moved in the Z-direction in the state where it is kept horizontal, and maintenance jobs for the replacement of the mask M, etc. are facilitated.

(Gap Adjustment Between Mask and Work)

The gap adjustment between the mask M and the work W is performed by minutely rotating the first Z-axis motors 21 and 21 and the second Z-axis motor 51. More specifically, when the work W and the mask M are already in a horizontal state, the first Z-axis motors 21 and 21 and the second Z-axis motor 51 are slightly rotated in synchronism, whereby the gap adjustment is made so as to establish a predetermined gap by bringing the mask holder 16 close to or away from the work W in the state where it is kept horizontal. Incidentally, the gap between the mask M and the work W is measured by a gap sensor 153 to be stated later, and the rotations of the first Z-axis motors 21 and 21 and the second Z-axis motor 51 are controlled on the basis of the measurement value of the sensor.

In a case where the work W and the mask M are not parallel, any motor among the first Z-axis motors 21 and 21 and the second Z-axis motor 51 is rotated at a rotation number higher or lower than those of the other motors, whereby the inclination of the mask holder 16 is adjusted so as to become parallel to the work W (as a tilt correction). On this occasion, the inclinations of the mask holder 16 relative to the frame 13 within the X-Z plane and the Y-Z plane are allowed by the free rotations of the three cross joints 34, 34 and 64.

Besides, when the inclinations of the mask holder 16 relative to the frame 13 (within the X-Z and Y-Z planes) change, the span change amounts between the first and second drive mechanisms 11A, 11B and 12 in a top plan view change. In a case, for example, where the Z-directional moving distance based on the second Z-axis motor 51 (upward movement in FIG. 5) is larger than the Z-directional moving distance based on the first Z-axis motors 21 and 21, the mask holder 16 rotates about the side of the pair of first drive mechanisms 11A and 11B (strictly, the axis of the cross shaft 33 of the cross joint 34) within the X-Z plane and inclines an angle γ, as shown in FIG. 5. The span between the first drive mechanisms 11A and 11B and the second drive mechanism 12 in the top plan view, on this occasion, shortens to C×cos γ where C denotes the length between the first drive mechanisms 11A and 11B and the second drive mechanism 12. The span change amount (C(1−cos γ)) between the first drive mechanisms 11A and 11B and the second drive mechanism 12 before and after the mask holder 16 inclines, is absorbed in such a way that the guide rail 53a′ and the slider 53b′ of the linear guide 53 serving as the second guide are relatively moved in the X-direction.

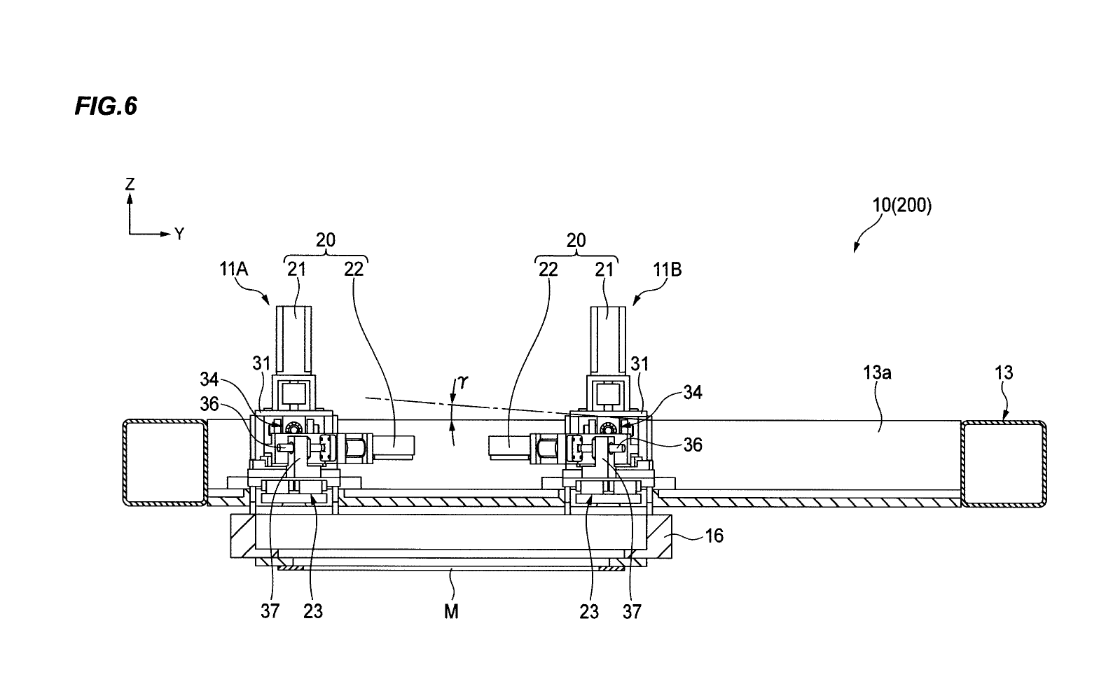

Likewise, when the mask holder 16 has inclined the angle γ from the horizontal state within the Y-Z plane (see FIG. 6), the span between the first drive mechanisms 11A and 11B in the top plan view, for example, shortens to D×cos γ where D denotes the length between the first drive mechanisms 11A and 11B. The span change amount (D(1−cos γ)) of the mask holder 16 between the first drive mechanisms 11A and 11B, attributed to the tilt, is absorbed in such a way that the guide rail 23a and slider 23b of the linear guide 23 serving as each first guide are relatively moved in the Y-direction.

As described above, according to the mask holding mechanism 10 of this embodiment, the pair of first drive mechanisms 11A and 11B and the second drive mechanism 12 being mechanisms in which the X-, Y-, Z- and θ-directional drives are integrated are employed, whereby the moving distances of the mask holder 16 at the time when the mask holder 16 has been X-, Y- and θ-driven, and the span change amounts between the drive mechanisms 11A, 11B and 12 in the top plan view, at the time when the mask holder 16 has been tilt-driven, can be absorbed by the linear guides 23 and 53 serving as the first and second guides. Thus, the drive mechanisms 11A, 11B and 12 of the mask holder 16 can be made small in size and light in weight, thereby to enhance a responsibility.

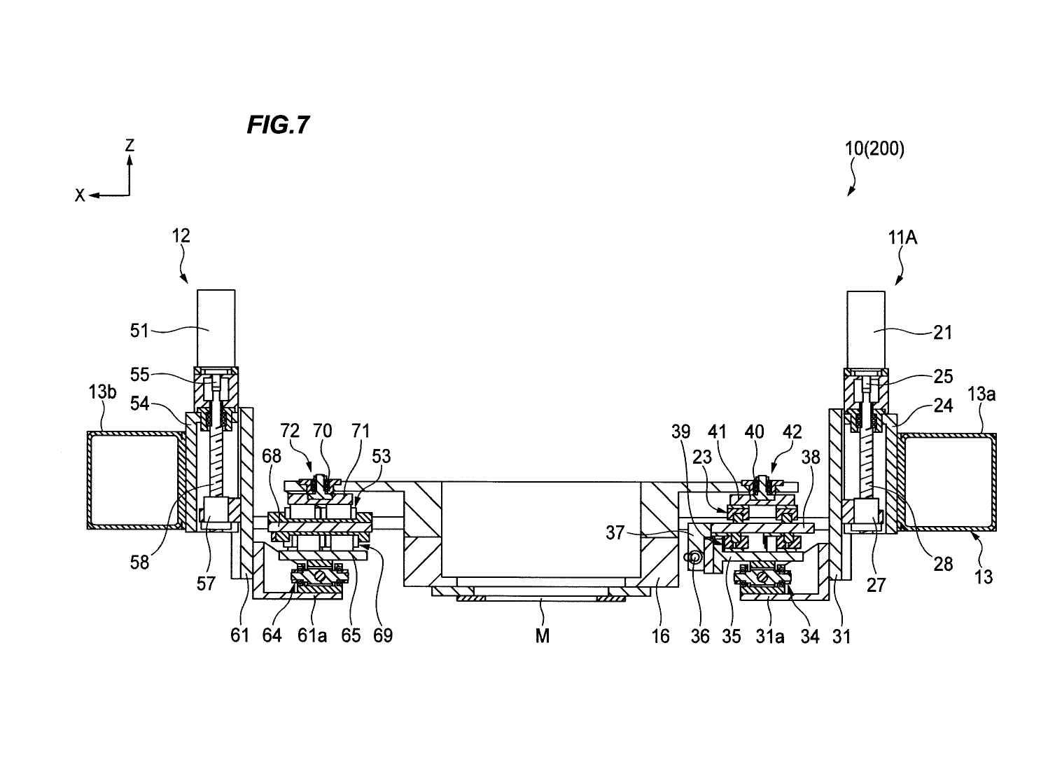

Incidentally, FIG. 7 is a sectional view corresponding to FIG. 4, of a mask holding mechanism in a modified embodiment. In the modified embodiment, respective overhang portions 31a and 61a are formed so as to spread out from the lower parts of the Z-axial movable bases 31 and 61 toward the inner side of the frame 13 (in the X-direction). In addition, the cross joints 34 and 64, the X-axis motor base 35 and Y-axis motor base 65, the linear guides 39 and 69 serving as the third and fourth guides, the first and second guide plates 38 and 68, the linear guides 23 and 53 serving as the first and second guides, and the rotary bases 41 and 71 are arranged on the overhand portions 31a and 61a in the order from below, and they support the mask holder 16 from above. Thus, the mask holding mechanism 10 can be compacted by making the height-wise dimension of the mask holding mechanism 10 smaller than in the arrangement example shown in FIG. 5.

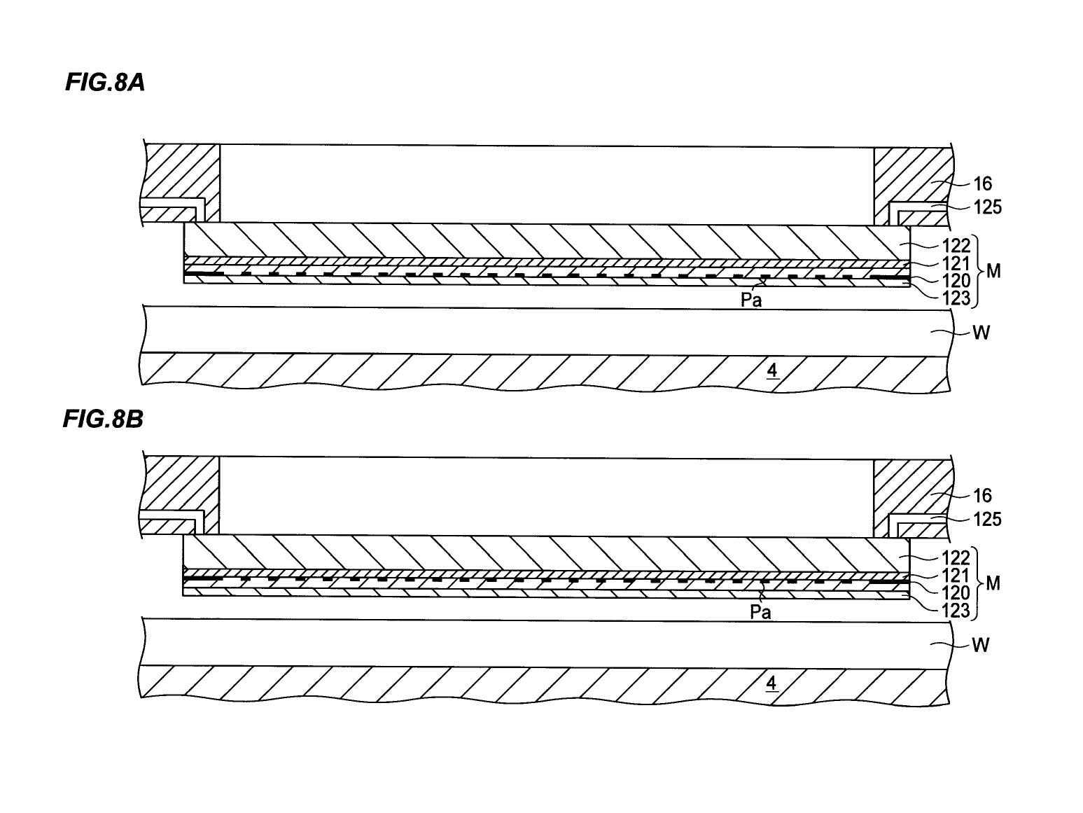

Incidentally, the mask M may be formed such that the pattern of chromium is directly formed on the lower surface of the glass plate, but it may be configured using a film mask 120 as in a modified embodiment shown in FIG. 8A. More specifically, the mask M of the modified embodiment further includes the film mask 120 which is formed with a pattern Pa, the glass plate (transparent medium) 122 onto which the film mask 120 is bonded through a resin layer 121 and a hard coat layer 123 which covers the surface of the film mask 120 opposite to the surface thereof bonded on the glass plate 122.

The glass plate 122 is absorbed and held on the mask holder 16 in such a way that the film mask 120 is drawn by suction through a pump (not shown) from a suction port 125 formed in the mask holder 16, in a state where this film mask is arranged on the side of the work W with respect to the glass plate 122, in other words, below.

In this manner, the film mask 120 is bonded on the glass plate 122, whereby the dimensional changes of the film mask 120 attributed to a temperature, a humidity, etc. are restrained and relieved by the glass plate 122, and the distortion of the film mask 120 attributed to the vacuum suction does not occur. Moreover, in changing the pattern Pa, only the film mask 120 may be replaced, and hence, a running cost can be lowered.

Incidentally, the film mask 120 may be formed with the pattern Pa on the surface opposite to the surface facing the glass plate 122. However, in a case where the pattern Pa is formed on the surface facing the glass plate 122 as in a modified embodiment shown in FIG. 8B, the damage of the pattern Pa can be prevented, and the durability of the mask M can be improved. Moreover, the hard coat layer 123 need not be provided as shown in FIG. 8B. Further, the transparent medium on which the film mask 120 is bonded may be a transparent member which has a predetermined thickness to the extent of providing a dimensional stability, and it is not limited to the glass plate 122, but it may be a plate material of resin or the like.

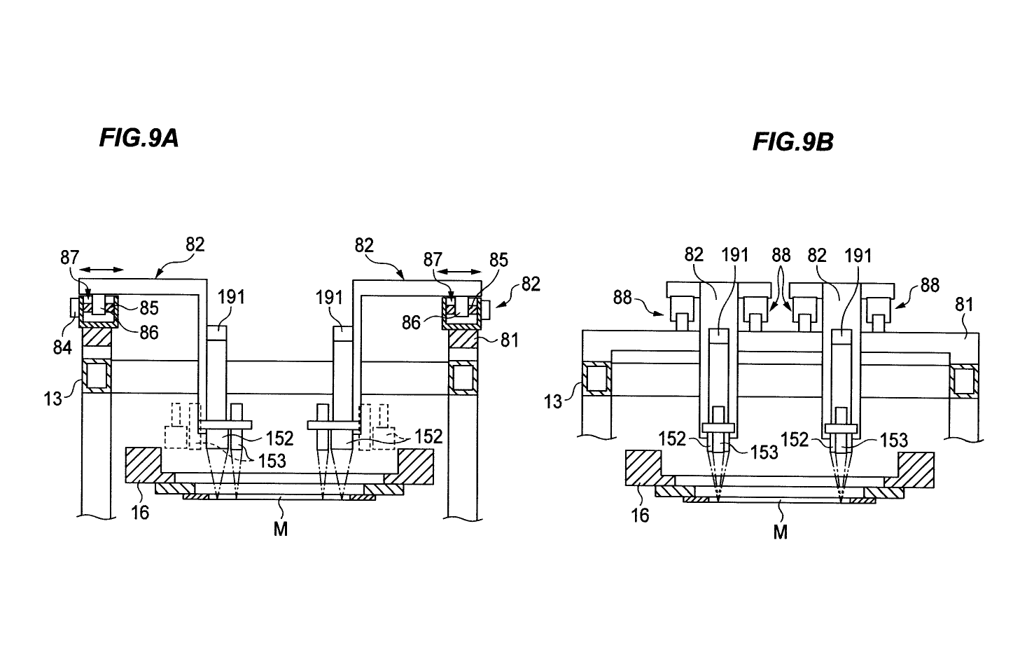

Besides, as shown in FIG. 2 and FIGS. 9A and 9B, a pair of frames 81 for carriers are mounted over the two opposing sides 13c and 13d of the frame 13, and a plurality of (four in this embodiment) sensor carriers 82 each including an alignment detection system 152 and a gap sensor (gap detection system) 153 are arranged on the pair of frames 81 so as to be drivable by detection system drive mechanisms 83. By the way, in FIG. 2, only the alignment detection system 152 and the gap sensor 153 disposed on one sensor carrier 82 are shown, and the alignment detection systems 152 and the gap sensors 153 mounted on the remaining sensor carriers 82 are omitted from illustration.

The detection system drive mechanism 83 includes a carrier drive motor 84 which is capable of driving the sensor carrier 82 in the Y-direction, a ball screw mechanism 87 which includes a screw shaft 85 that is rotated by the motor 84 and a nut 86 that is in threadable engagement with the screw shaft 85, and a pair of linear guides 88 which guide the sensor carrier 82 in the Y-direction on both the sides of the ball screw mechanism 87.

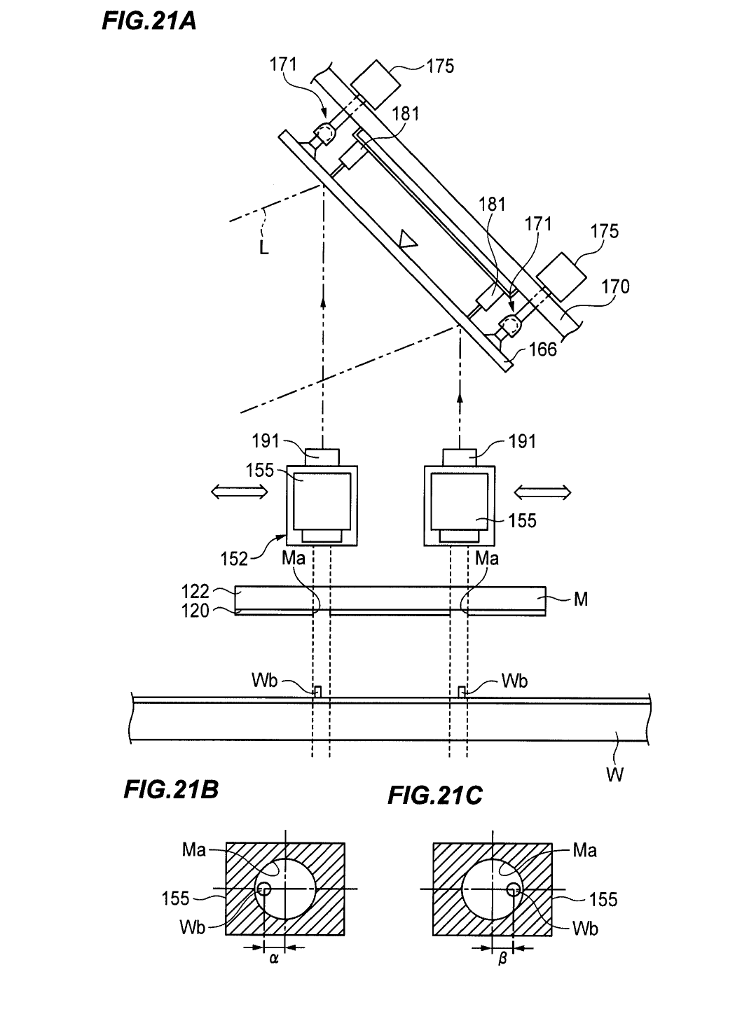

The alignment detection system 152 includes CCD cameras 155 (see FIG. 21), and besides, objective lenses, mirrors, illumination means (not shown) and it images an alignment mark Ma on the side of the mask and an alignment mark Wb on the side of the work by the CCD cameras 155. Besides, the gap sensor 153 includes a laser light emission portion and a laser light reception portion (not shown) and laser lights reflected from the lower surface of the mask M and the upper surface of the work W are detected by a line sensor configured of the laser light reception portion.

Accordingly, the alignment detection system 152 and the gap sensor 153 are respectively permitted to retreat to a position where the alignment detection system 152 can visually recognize the alignment mark of the mask side, and a position where the gap sensor 153 can detect the lower surface of the mask M, in the vicinities of the four corners of the rectangular mask by the sensor carrier 82. Thus, the alignment adjustment of the mask M is performed by the mask drive mechanism 200 while the corresponding alignment marks Ma formed on the mask M, and the alignment marks Wb of the work W are being imaged and detected by the alignment detection systems 152.

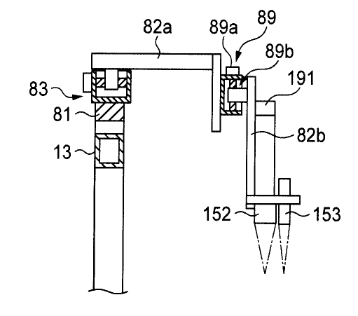

Incidentally, as shown in FIG. 10, the alignment detection system 152 and the gap sensor 153 may be driven in the Z-direction in such a way that the sensor carrier 82 is divided into two members 82a and 82b, and that a Z-directional drive mechanism 89 which includes a motor 89a, a ball screw mechanism 89b, and linear guides (not shown) is disposed between the members 82a and 82b.

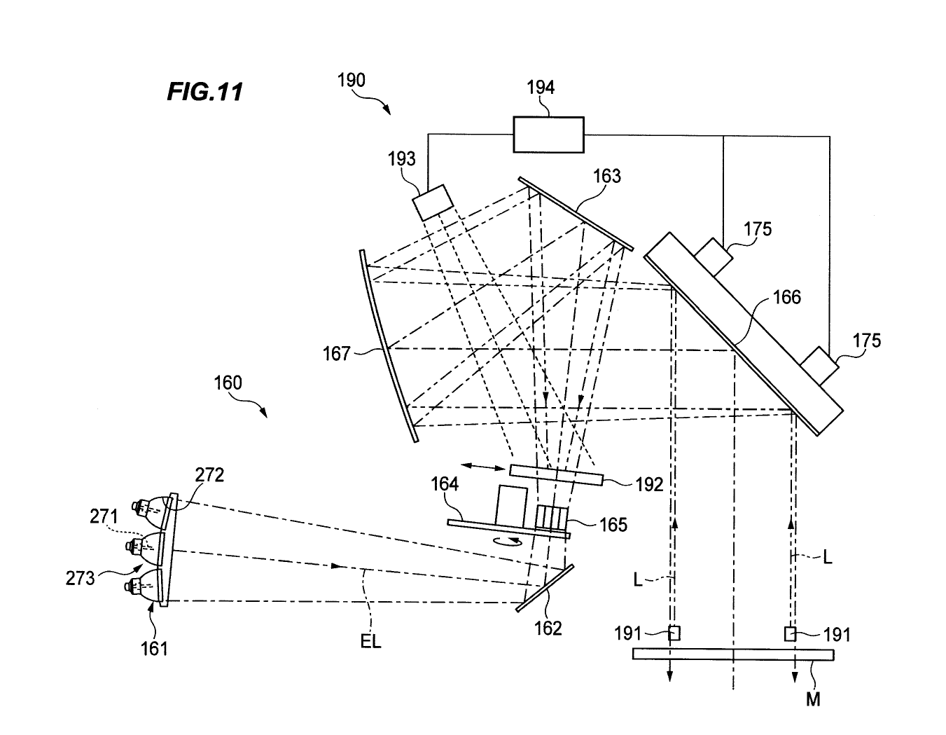

As shown in FIG. 11, an illuminating optical system 160 includes a multi-lamp unit 161 which includes a plurality of light sources 273, each including a light source for ultraviolet radiation, for example, a high-pressure mercury-vapor lamp 271, and a reflector 272 as a reflecting optical system for condensing light projected from the high-pressure mercury-vapor lamp 271 and emitting the condensed light with a directionality, a plane mirror 162 which serves to change the direction of an optical path EL, a shutter unit 164 for an exposure control, which controls the optical path EL to be opened and shut, an optical integrator 165 which is arranged on the downstream side of the exposure-controlling shutter unit 164 and from which the light condensed by the reflector 272 emerges so as to become an illuminance distribution being uniform to the utmost in a projection area, a plane mirror 163 which serves to change the direction of the optical path EL emergent from the integrator 165, a collimation mirror 167 by which the light from the high-pressure mercury-vapor lamp 271 is projected as collimated light, and a plane mirror 166 which projects the collimated light toward the mask M. Incidentally, a DUV-cut filter, a polarization filter and a band-pass filter may be arranged between the optical integrator 165 and an exposure surface. The illuminating optical system 160 may use a single high-pressure mercury-vapor lamp instead of the multi-lamp unit 161. Besides, as the light source, an LED may be applied instead of the ultrahigh-pressure mercury-vapor lamp 271

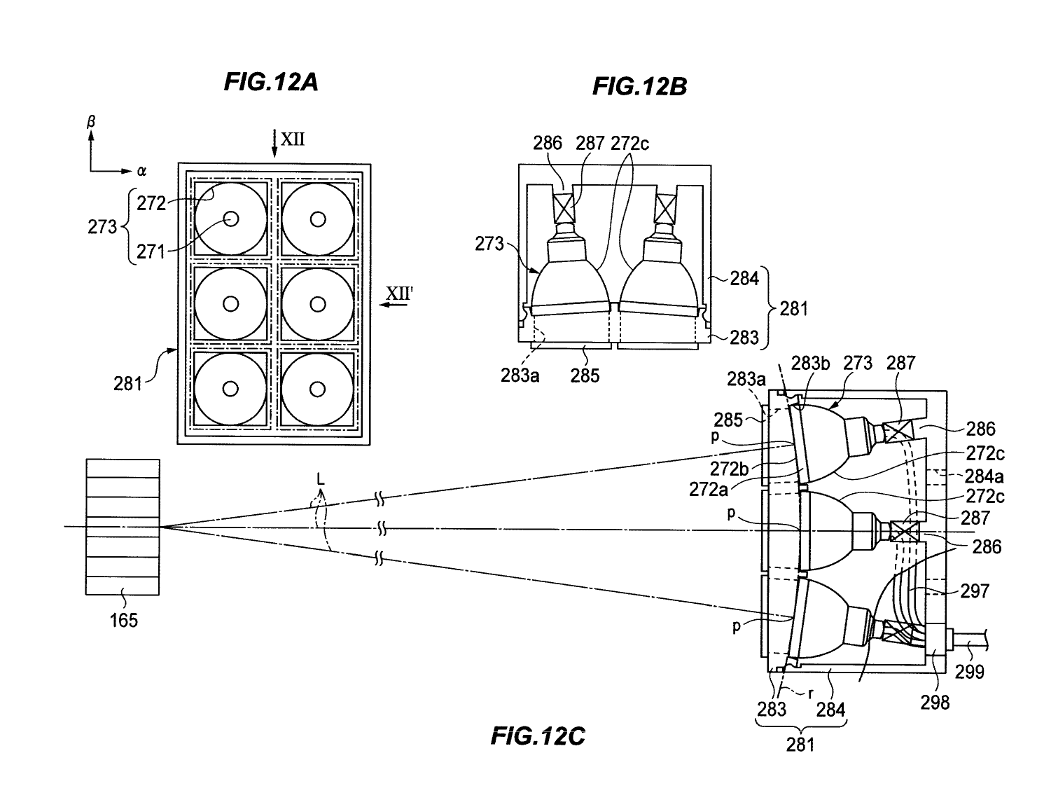

As shown in FIG. 12A to FIG. 14, the plurality of light sources 273 are mounted in a cassette 281 in the multi-lamp unit 161. The cassette 281 is formed in a rectangular shape in which the light sources 273 are arranged in numbers which are different in α- and β-directions. Besides, in the light source 273 of this embodiment, the opening 272b of the reflector 272 is formed in a substantially square shape, in which four sides are arranged so as to extend along the α- and β-directions.

The cassette 281 is formed substantially in the shape of a rectangular parallelepiped, which includes a light source support 283 which supports the light sources 273 in a predetermined number, and a concave lamp keeper cover (cover member) 284 which keeps the light sources 273 supported by the light source support 283 and which is attached to this light source support 283.

The light source support 283 is formed with a plurality of windows 283a which are provided in correspondence with the number of the light sources 273 and each of which emits light from the corresponding light source 273, and recesses for the lamps, 283b which are provided on the cover sides of the windows 283a and each of which surrounds the opening 272a of the corresponding reflector 272 (or the opening of a reflector mounting portion for mounting the corresponding reflector 272). Besides, a plurality of cover glasses 285 are respectively mounted on the sides of the windows 283a opposite to the covers thereof. Incidentally, the cover glasses 285 may be mounted arbitrary and need not be always disposed.

The bottom surface of each recess for the lamp, 283b is formed into a plane or a curved surface (plane in this embodiment) so that the intersection point p between a projection plane for projecting the light of the light source 273 (here, the opening surface 272b of the reflector 272) and the optic axis L of the light source 273 may be located on a single curved surface, for example, a spherical surface r in the respective α- and β-directions.

Contact portions 286 each of which contacts on the rear part of the corresponding light source 273 is provided at the bottom surface of the lamp keeper cover 284, and a lamp keeper mechanism 287 which is configured of an actuator such as motor or cylinder, a spring retainer, a screw plug, etc. is disposed in each contact portion 286. Thus, each light source 273 is positioned in the cassette 281 in such a way that the opening 272a of the reflector 272 is fitted with the recess 283b for the lamp of the light source support 283, that the lamp keeper cover 284 is attached to the light source support 283, and that the rear part of the light source 273 is pressed by the lamp keeper mechanism 287. As shown in FIG. 12C, accordingly, the distances of the individual optic axes L from the respective projection planes from which the lights of the predetermined number of light sources 273 positioned in the cassette 281 are projected, to that entrance plane of the integrator lens 274 into which the lights of the predetermined number of light sources 273 are entered, become substantially constant.

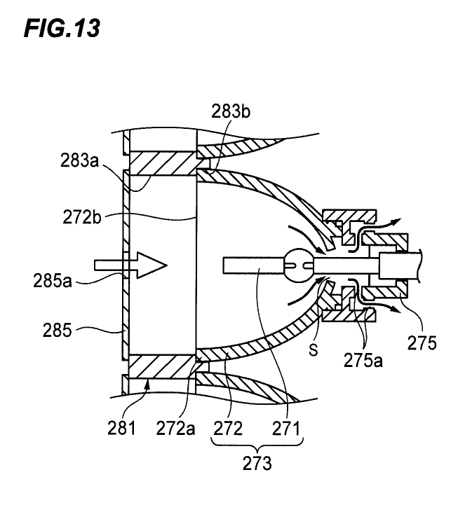

As shown in FIG. 13, a base portion 275 on which the lamp 271 and reflector 272 of each light source 273 are mounted is formed with a cooling passage 275a having a space s, and each cover glass 285 of the cassette 281 is formed with one or more penetrating holes 285a. Besides, in the accommodation space between the light source support 283 and the lamp keeper cover 284, the rear surfaces 272c of the reflectors 272 of the adjacent light sources 273 oppose directly to each other, and the flow of air within the accommodation space is not interrupted by any other than the light sources 273, the lamp keeper mechanisms 287, etc., so that a good air flowability is provided. Owing to these configurations, the good cooling performance of each lamp 271 is provided. Incidentally, the cassette keeper cover 284 may be provided with communicating holes or communicating grooves so as to provide the air flowability, as a skeleton structure constituted by a plurality of frames, or it may be brought into a mesh shape.

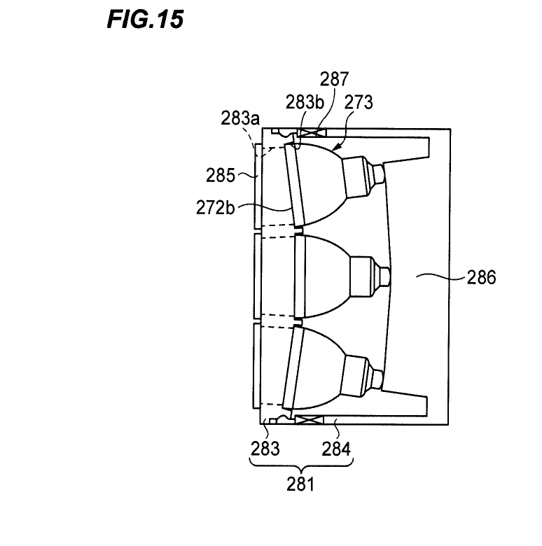

Besides, the lamp keeper mechanism 287 may be disposed every contact portion 286, but it may be formed on the side wall of the lamp keeper cover 284 as shown in FIG. 15. Also in this case, the contact portion 286 may be disposed for each individual light source 273, but it may abut on the rear parts of the two or more light sources 273.

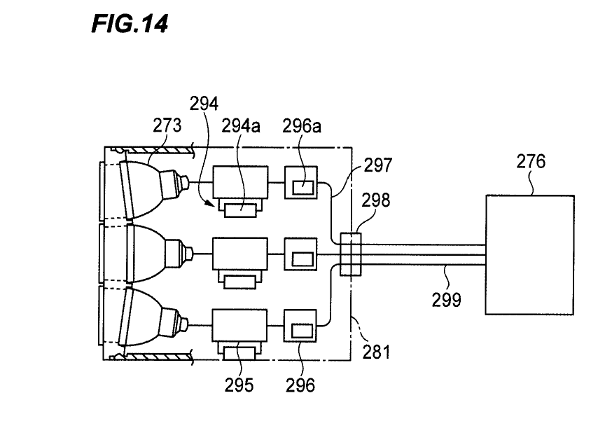

As shown in FIG. 14, lighting power sources 295 and control circuits 296 for feeding powers to the lamps 271 are individually connected to the light sources 273 of the cassette 281, and wiring lines 297 extending rearwards from the respective light sources 273 are connected to and collected by a connector 298 disposed in the cassette 281. In addition, the connector 298 of the cassette 281 and an optical controller 276 disposed outside a frame 282 are connected by other individual wiring lines 299. Thus, the optical controller 276 transmits control signals to the control circuits 296 of the respective lamps 271, thereby to perform a voltage control for adjusting a voltage, including lighting and putting-out, for each lamp 271.

Incidentally, the lighting power sources 295 and control circuits 296 of the respective light sources 273 may be collectively disposed in the cassette 281 and may be disposed outside the cassette. Besides, the contact portions 286 of the lamp keeper cover 284 are formed so as not to interfere with the individual wiring lines 297 from the respective light sources 273.

Further, lifetime detection means 294 including a fuse 294a is disposed every lamp 271, a lighting time period is counted by a timer 296a, and at a stage when a rated lifetime has been reached, a current is caused to flow through the fuse 294a, and the fuse 294a is burnt out. Accordingly, it can be detected whether the lamp 271 has been used for the rated lifetime by checking the blow of the fuse 294a. Incidentally, the lifetime detection means 294 is not restricted to one including the fuse 294a, but it may have any structure with which the rated lifetime of the lamp 271 is recognized at a glance at the maintenance of a lamp replacement. The lifetime detection means may be, for example, one in which an IC tag is arranged every lamp 271 and in which whether the lamp 271 has been used for the rated lifetime can be checked with the IC tag, or in which the time period of use of the lamp 271 can be checked.

In addition, when the exposure controlling shutter unit 164 is controlled to open at the time of exposure, lights projected from the multi-lamp unit 161 are projected onto the mask M held on the mask holder 16, in turn, the front surface of the work W through the plane mirror 162, the optical integrator 165, the plane mirror 163, the collimation mirror 167 and the plane mirror 166, as lights for the pattern exposure, and the exposure pattern of the mask M is transferred onto the work W by the exposure.

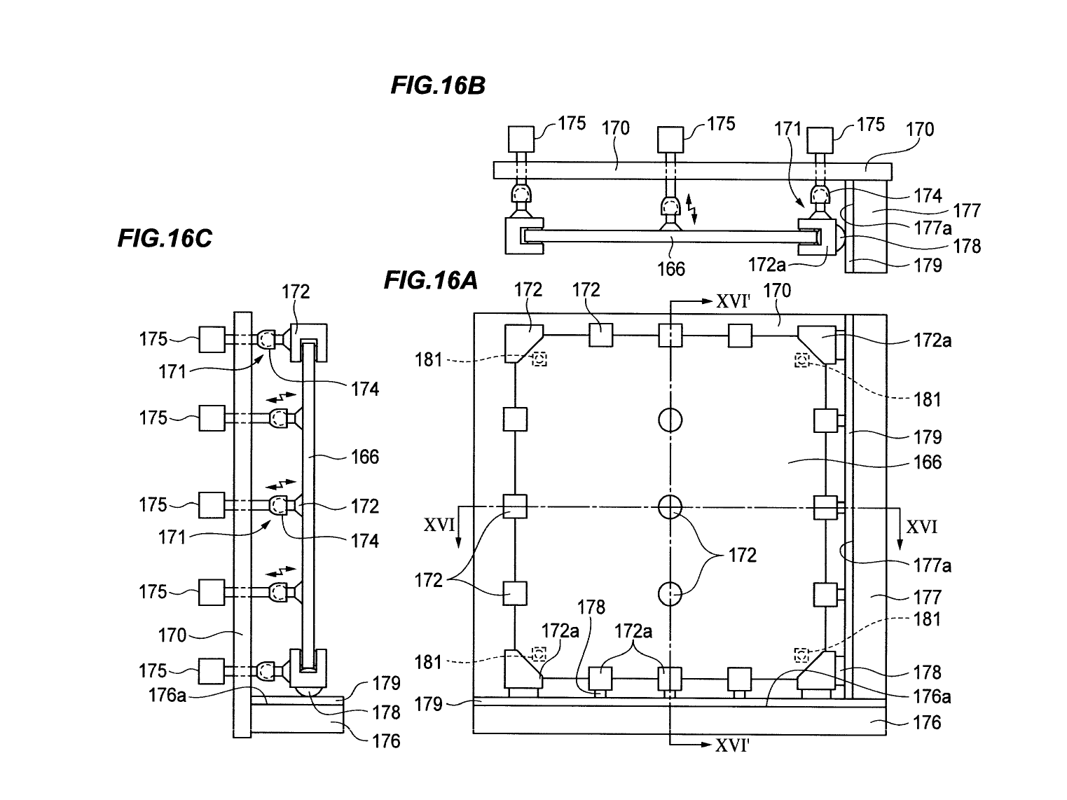

As shown in FIG. 16, the plane mirror 166 is made of a glass material which is formed in the shape of a rectangle in a front view. A plurality of support mechanisms 171 fixed to a support mechanism holding frame 170 are disposed as reflector support structures, in three places near the center of the rear surface of the plane mirror 166 and in 16 places at the peripheral part thereof. In each support mechanism 171 disposed near the center, the support 172 is fixed to the rear surface of the plane mirror 166 with an adhesive, and in each support mechanism 171 disposed at the peripheral part, the supports 172 and 172a thereof are fixed with the adhesive in a manner to hold the front and rear surfaces of the plane mirror 166. Besides, a ball joint 174 serving as a crook mechanism which allows a crook of, at least, ±0.5 deg is disposed at a position near the support 172 or 172a of each support mechanism 171, and a motor 175 being support mechanism drive unit is attached to the support mechanism holding frame 170 at the end part thereof opposite to the side of the support.

Incidentally, each support mechanism 171 at the center of the plane mirror 166 may have a structure which is fixed to the support mechanism holding frame 170.

Besides, guide members 176 and 177 are mounted on the rectangular support-mechanism holding frame 170, at the positions of two sides orthogonal to each other, and rolling members 178 are mounted on the side surfaces of supports 172a opposing to these guide members 176 and 177. Besides, those guide surfaces 176a and 177a of the guide members 176 and 177 which guide the rolling members 178 are coated with low-friction mechanisms 179 of “Teflon” (registered trademark) or the like.

Further, a plurality of touch type sensors 181 are mounted on the positions of the rear surface of the plane mirror 166 which reflects the exposure light to the positions of the alignment marks Ma on the mask side.

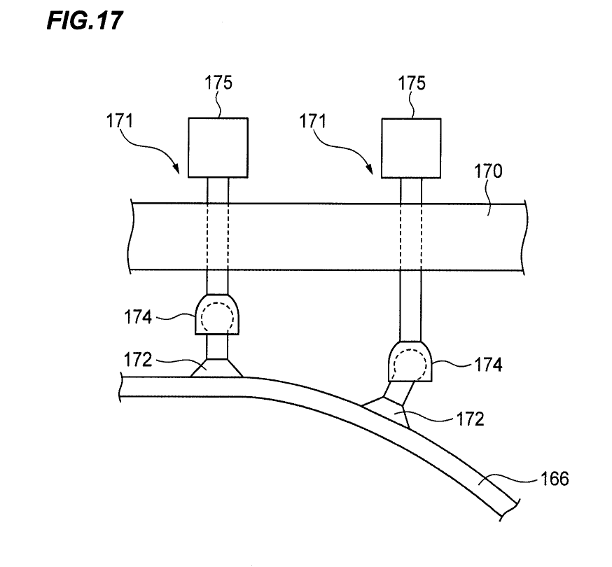

Thus, while sensing the displacement amounts of the plane mirror 166 by the touch type sensors 181, the individual support mechanisms 171 change their lengths to rectilinearly move the supports 172, by driving the motors 175 of the respective support mechanisms 171 disposed in the support mechanism holding frame 170. In addition, while being guided by the two guide members 176 and 177 through the rolling members 178 disposed in the supports 172, by the different lengths of the individual support mechanisms 171, the plane mirror 166 has its curvature corrected locally and can correct its declination angle. On that occasion, since the individual support mechanisms 171 are provided with the ball joints 174, the portions of the support side are rotatable in three dimensions, and the individual supports 172 can be inclined along the front surface of the plane mirror 166 as shown in FIG. 17. Therefore, stresses at positions near the individual supports 172 in the plane mirror 166, between the respective supports 172 of different moving distances, are restrained from enlarging. Accordingly, even in a case where the plane mirror 166 is made of a glass material of small average breaking stress value, a stress which is generated in the glass in locally correcting the curvature of the plane mirror 166 can be made smaller than in the prior art, and the plane mirror 166 can be curved in the order of 10 mm without damaging the plane mirror 166 and can alter the curvature largely.

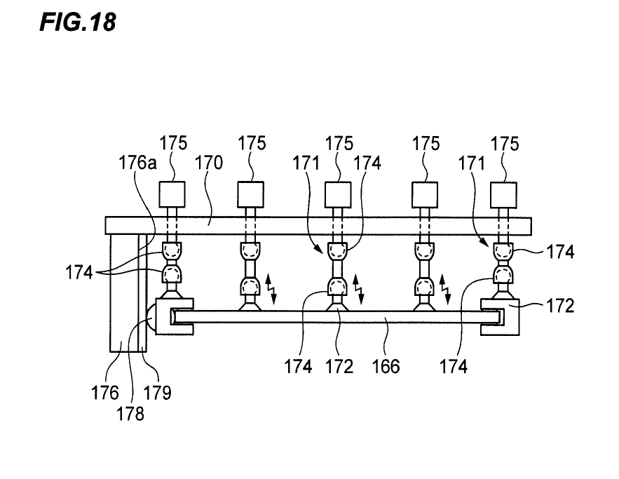

Incidentally, as shown in FIG. 18, each support mechanism 171 may have a plurality of (in FIG. 7, two) ball joints 174. In this case, the bending amount of the plane mirror 166 can be made the total of turning amounts based on the individual ball joints 174, and the plane mirror 166 can be bent more largely.

Besides, as shown in FIG. 11, there is disposed a curvature-correction-amount detection system 190 for judging if the curvature correction of the plane mirror 166 corresponding to the distortion amount of the work W has been made in the correction of the curvature of the plane mirror 166. The curvature-correction-amount detection system 190 includes a plurality of (in this embodiment, four) laser pointers 191 which are respectively arranged in the vicinities of the individual alignment detection systems 152, and which serve as laser light sources for projecting laser lights L as lights that have directivities toward the plane mirror 166 from the exposure surface side (in this embodiment, the vicinity of the mask) with respect to the plane mirror 166 in the optical path EL of the light beam of the exposure light, a reflection plate 192 which is arranged in the vicinity of the integrator 165 so as to be retreatable from the optical path EL of the light beam of the exposure light, a camera 193 which serves as an imaging device for imaging the laser light L that has fallen upon the reflection plate 192 through the plane mirror 166, and a controller 194 which is interposed between the camera 193 and the motors 175 of the support mechanisms 171 of the plane mirror 166, and which detects the displacement amounts S1 and S2 of the laser light L imaged in the correction of the curvature of the plane mirror 166 and controls the motors 175 of the support mechanisms 171 so that the displacement amounts S1 and S2 may correspond to a calculated distortion amount.

The laser pointer 191 is attached to the upper part of the alignment detection system 152, for example, a CCD camera 155, and it is moved in synchronism with the advance and withdrawal of the alignment detection system 152 to and from a position where the alignment mark of the mask side can be visually recognized. Incidentally, the laser pointer 191 may be advanced and withdrawn to and from over the mask by the sensor carrier 82 which is independent of the alignment detection system 152.

Since the reflection plate 192 is arranged in the vicinity of the integrator which provides the most condensed light by reflection based on the collimation mirror 167, the laser lights L from the four laser pointers 191 as have been reflected by the plane mirror 166, the collimation mirror 167 and the plane mirror 163 can be grasped by the reflection plate 192 of comparatively small area. Besides, the reflection plate 192 is arranged so as to be retreatable from the optical path EL of the light beams of the exposure lights from the light sources, through the sensor carrier 82 by the detection system drive mechanism 83 when the light beams are projected onto the mask M in the ordinary exposure. Further, the reflection plate 192 is endowed with a reflective surface of low reflection factor, whereby the visibilities of the laser lights L in the camera 193 can be heightened.

The camera 193 is arranged at a position which is distant from the optical path EL of the light beams from the light sources, so as not to exert influence on the light beams of the exposure light.

Besides, the controller 194 detects the positions of the laser lights L imaged by the camera 193, as the displacement amounts S1 and S2 before the curvature correction and after the curvature correction, it checks if the displacement amounts S1 and S2 correspond to the distortion amounts α and β of the work W, and it provides control signals to the motors 175 of the support mechanisms 171 of the plane mirror 166.

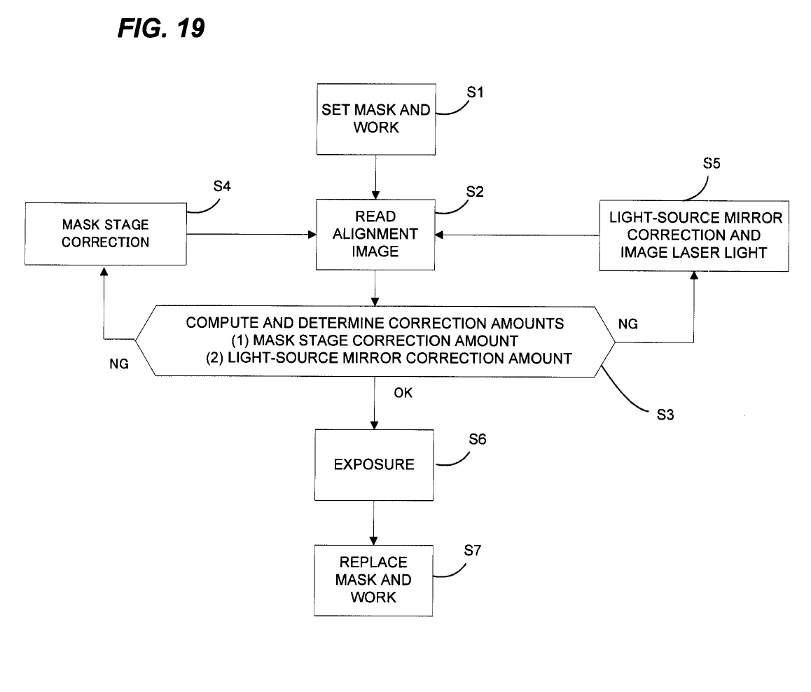

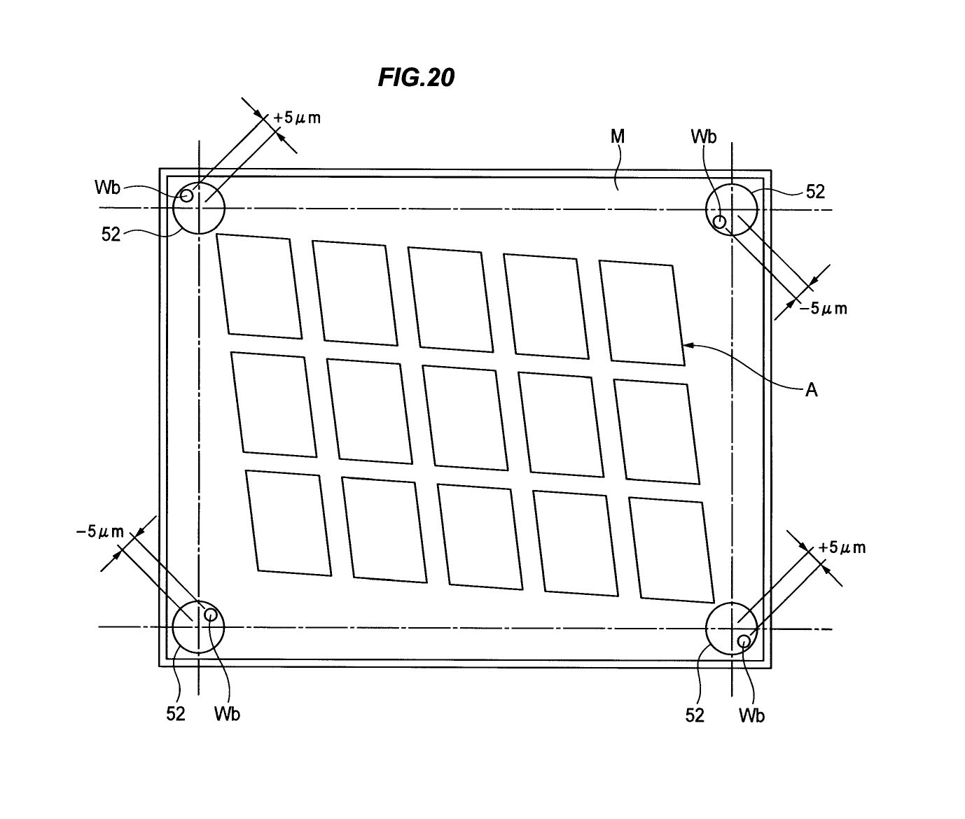

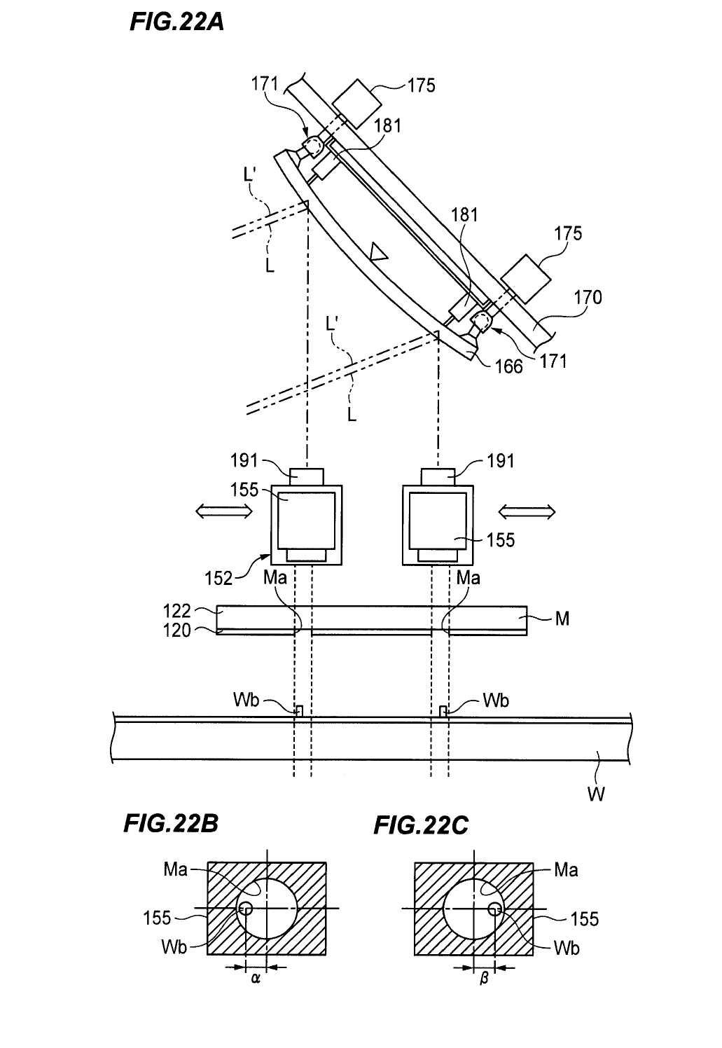

Next, the exposure method of this embodiment will be described with reference to FIGS. 19 to 23. Here, when the part to-be-exposed of the conveyed hoop-shaped work W is brought into the shape of a flat plate in the exposure area P, the part to-be-exposed sometimes becomes parallelogrammic without becoming rectangular, due to the distortion of the work W (see FIG. 20). A case where such a work W is exposed, will be described below, and the CCD cameras 155 located at the diagonal positions of the work shall be shown in FIGS. 21 and 22.

First, the work W is conveyed to the exposure area P where the mask M lies (step S1), and after the part A to-be-exposed has been drawn by suction by the work chuck 4, the alignment marks Wb of the work W and the alignment marks Ma of the mask M are detected by the CCD cameras 155 in four places (step S2). In addition, the positional shift amount between the center of the mask M and that of the work W and the distortion amount of the work W are separately computed on the basis of the shift amounts between both the alignment marks Wb and Ma, which are detected by the individual CCD cameras 155, by the controller (not shown). Subsequently, it is determined if the positional shift amount between the center of the mask M and that of the work W, and the distortion amount of the work W are within allowable values, respectively. (Step S3)

In a case where the positional shift amount between the center of the mask M and that of the work W exceeds the allowable value, a correction amount based on the mask drive mechanism 200 is calculated as a command value. In a case where the distortion amount of the work W exceeds the allowable value, the correction amount of the plane mirror 166, concretely, the moving distance of each support mechanism 171 is calculated as a command value.

In addition, at a step S4, the mask drive mechanism 200 for aligning the mask M is driven and controlled in the X-, Y- and θ-directions, whereby the alignment (shift correction) between the work W and the mask M is made. Thus, as shown in FIG. 20, the total of the positional shift amounts between the centers of the individual alignment detection systems 152, that is, the individual alignment marks Ma of the mask M, and individual alignment marks Wb of the work W becomes the minimum, and the shifts between the alignment marks Ma of the mask M and the alignment marks Wb of the work W become chiefly ascribable to the distortion of the work W.

Subsequently, at a step S5, in order to conform to the shape of the part to-be-exposed of the work W, the curvature of the plane mirror 166 is corrected to correct the declination angle of the exposure light. Concretely, the command values concerning the moving distances of the individual support mechanisms 171 are fed to the individual motors 175 on the basis of the distortion amounts α and β of the work W as shown in FIG. 21, and the individual motors 175 are driven and controlled while checking the displacement amounts of the plane mirror 166 with the touch type sensors 181.

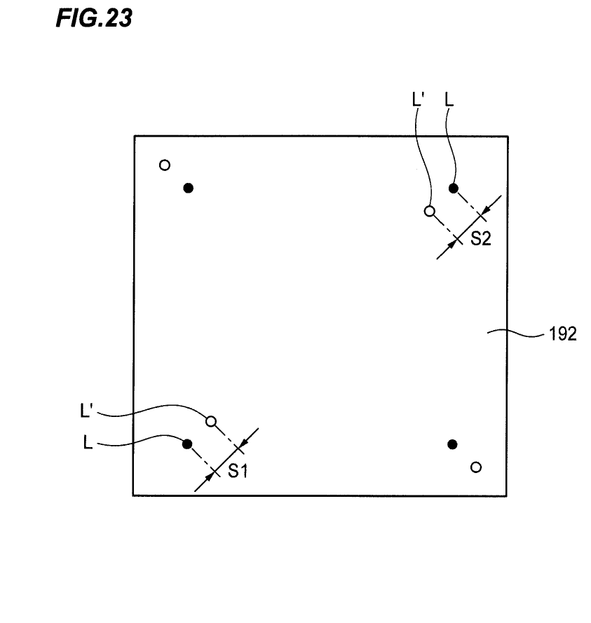

Besides, in the curvature correction, the reflection plate 192 is advanced over the optical path of the light beam of the exposure lights, and the laser pointers 191 of the alignment detection systems 152 advanced over the mask M by the detection system drive mechanism 83 project the laser lights L toward the plane mirror 166. Thus, the camera 193 images the laser lights L (black dots in FIG. 23) before the curvature correction and the laser lights L′ (white dots in the figure) after the curvature correction as have fallen upon the reflection plate 192, as shown in FIG. 23.

In addition, after the correction with the mask drive mechanism 200 and the correction with the plane mirror 166 have been made, the alignment marks Wb of the work W and the alignment marks Ma of the mask M are detected by the CCD cameras 155 in the four places, at the step S2 again. Here, as apparent from FIGS. 22B and 22C, the CCD camera 155 cannot receive light passing through the plane mirror 166, because it is located on the optical path side of the mask M. Therefore, the CCD camera 155 cannot detect the positions of both the alignment marks remedied by the bending correction of the plane mirror 166, and it detects the alignment mark Wb of the work W and the alignment mark Ma of the mask M after the correction with the mask drive mechanism 200, as in FIGS. 21B and 21C. Accordingly, it is determined if the correction amount with the mask drive mechanism 200 based on the positional shift amount between the center of the mask M and that of the work W is within the allowable value at the step S3 after the correction.

Besides, at the step S3, the controller 194 detects the positions of the laser lights L and L′ imaged by the camera 193, as the displacement amounts S1 and S2 before the curvature correction and after the same, and it checks if these displacement amounts S1 and S2 correspond to the distortion amounts α and β of the work W, concretely, if the displacement amounts S1 and S2 of the laser lights L and L′ are within allowable ranges with respect to values corresponding to the distortion amounts α and β of the work W. In addition, until the displacement amounts S1 and S2 fall within the allowable ranges of the values corresponding to the distortion amounts α and β of the work W, the control signals are provided to the motors 175 of the support mechanisms 171 of the plane mirror 166, and the curvature corrections with the plane mirror 166 are made.

Thereafter, in a case where the positional shift amount and the distortion amount computed at the step S3 are within the allowable values, the exposure method proceeds to a step S6. In addition, while the gap between the mask M and the work W is being measured by the four gap sensors 153, the mask holder 16 is driven in the Z-direction to the operation position by the mask drive mechanism 200, thereby to make a gap adjustment so that the gap between the mask M and the work W may become a predetermined gap. Besides, the gap adjustment is performed so that individual gaps in the vicinities of the four corners may become the predetermined gap, and the mask M is tilt-corrected so that the lower surface of the mask M may become parallel to the upper surface of the work W. In addition, the light beam EL of the exposure light from the illuminating optical system 160 is projected onto the work W through the mask M, thereby to transfer the pattern of the mask M onto the work W.

In addition, the exposure light is projected toward the mask M from the illuminating optical system 160 which is arranged over the mask M, and it is projected onto the part to-be-exposed A of the work W (as, for example, a ground pattern). Thus, the pattern of the mask M is transferred by the exposure onto the front surface of the work W in a state where it coincides with the part to-be-exposed A of the work W. Incidentally, during the exposure, the part to-be-exposed A of the work W may be stationary in the exposure area P, and the delivery by the delivery device 1 or/and the take-up by the take-up device 2 may be simultaneously performed.

Besides, in the case where the film mask 120 bonded on the glass plate 122 is used as the mask M, the dimensional change of the film mask 120 is constrained by the glass plate 122, and the exposure of high precision becomes possible.

By the way, in the embodiment, the curvature correction of the plane mirror 166 is made after the alignment between the work W and the mask M has been adjusted, but a tact time may be shortened by simultaneously performing the alignment adjustment and the curvature correction of the plane mirror 166. Besides, after the positional shift amount has become within the allowable value by performing the alignment adjustments a plurality of times, the curvature correction of the plane mirror 166 may be made after the gap adjustment between the mask M and the work W.

As described above, according to the proximity exposure apparatus of this embodiment, in the state where the part to-be-exposed A of the work W conveyed into the exposure area P is kept stationary and where the work W and the mask M are brought into proximity with the predetermined gap, the light beam of the exposure lights from the illuminating optical system 160 is projected onto the work W through the mask M, thereby to transfer the pattern of the mask M onto the work W. Here, the proximity exposure apparatus includes at least two alignment detection systems 152 which detect the alignment mark Wb of the work W and the alignment mark Ma of the mask M, respectively, at least three gap sensors 153 which detect the gaps between the work W and the mask M located in the exposure area P, respectively, and the mask drive mechanism 200 which can drive the mask holder 16 in the X-direction and Y-direction orthogonal to each other on the horizontal plane and can tilt and drive the mask holder 16 in the θ-direction round the axis orthogonal to the horizontal plane, wherein the mask drive mechanism 200 adjusts the alignment between the work W and the mask M by driving the mask holder 16 on the horizontal plane, on the basis of the shift amount between both the alignment marks Wb and Ma, which is detected by the alignment detection systems 152, and the mask drive mechanism 200 corrects the relative inclination between the work W and the mask M, by tilting and driving the mask holder 16 on the basis of the gaps detected by the gap sensors 153. Accordingly, in conveying the work W and exposing the work W to the exposure light in the stationary state in the exposure area P, the exposure can be performed after the alignment adjustment, and the tilt correction for uniformalizing the gap between the work W and the mask M, so that the pattern of the mask M can be precisely transferred by the exposure.

Moreover, since the alignment detection systems 152 and the gap sensors 153 are moved by the identical detection system drive mechanism 83, drive mechanisms need not be individually disposed, and a compact configuration can be attained.

Further, the illuminating optical system 160 includes the light sources 161, the plane mirror 166 which reflects the light beam of exposure lights from the light sources 161, the support mechanisms 171 which support the peripheral parts or rear surface of the plane mirror 166, and the motors 175 which can move the support mechanisms 171, wherein the mask drive mechanism 200 adjusts the alignment between the work W and the mask M by driving the mask holder 16 on the horizontal plane on the basis of that positional shift amount between the mask M and the work W, which is calculated from the shift amount between both the alignment marks which is detected by the alignment detection system 152, and the plane mirror 166 locally corrects its curvature by moving the support mechanisms 171 through the motors 175 on the basis of that distortion amount of the work W which has been calculated from the shift amount between both the alignment marks as has been detected by the alignment detection system 152. Thus, even in a case where the work W has been distorted, the pattern of the mask M can be precisely transferred by exposure in conformity with the shape of the part to-be-exposed of the work W.

Further, the proximity exposure apparatus also includes the curvature-correction-amount detection system 190 having the laser pointers 191 which project the laser lights L toward the plane mirror 166 from the exposure surface side with respect to the plane mirror 166, the reflection plate 192 onto which the laser lights L reflected by the plane mirror 166 are projected, the camera 193 which images the laser lights L reflected on the reflection plate 192 through the plane mirror 166, and the controller 194 which detects the displacement amounts S1 and S2 of the laser lights L and L′ imaged when the curvature of the plane mirror 166 has been corrected, wherein the plane mirror 166 locally corrects its curvature by moving the support mechanisms 171 through the motors 175 so that the displacement amounts S1 and S2 of the laser lights L and L′ detected by the curvature-correction-amount detection system 190 at the correction of the curvature may correspond to the calculated distortion amounts α and β of the work W. Thus, the curvature of the plane mirror 166 can be corrected while detecting this curvature with the curvature-correction-amount detection system 190. Thus, even in a case where the work W has been distorted, the pattern of the mask M can be more precisely transferred by exposure in conformity with the shape of the part to-be-exposed of the work W.

The laser pointers 91 project the laser lights L toward the plane mirror 66 from the exposure surface side with respect to the plane mirror 66 in the optical path EL of the light beam of the exposure lights, and the reflection plate 62 is arranged so as to be retreatable from the optical path EL of the light beam of the exposure lights, in the vicinities of the integrators 65 of the illuminating optical systems 60a and 60b. Thus, the curvature-correction-amount detection system 90 can be disposed at a low cost with a space saved.

Besides, the mask drive mechanism 200 includes the pair of first drive mechanisms 11A and 11B each of which has the first drive portion 20 and the first guide 23, and the second drive mechanism which has the second drive portion 50 and the second guide 53. When the mask holder 16 has been driven in the X-direction or θ-direction by the first drive portion 20, the moving distance of the mask holder 16 is absorbed by the second guide 53. Also, when the mask holder 16 has been driven in the Y-direction by the second drive portion 50, the moving distance of the mask holder 16 is absorbed by the first guide 23. Further, when the mask holder 16 has been tilted and driven, the span change amount of the mask holder 16 attributed to the tilt thereof in the top plan view among the first and second drive mechanisms 11A, 11B and 12 is absorbed by at least one of the first and second guides 23 and 53. Thus, the X-, Y-, Z- and θ-directional drives and tilt drive of the mask holder 16 can be performed by the integrated mechanism. Thus, the drive mechanism of the mask holder 16 is made small in size and light in weight, so that the responsibility can be enhanced.

Besides, the mask holder 16 is made movable between the operation position proximate to the work W and the retreat position spaced from the work W, by the Z-directional drives of the first and second drive portions 20 and 50, so that the maintenance jobs for the mask replacement are facilitated, and job efficiency is heightened.

Further, the first drive portion 20 includes the X-axis motor 22, the X-axis motor base 35 on which the X-axis motor 22 is mounted, the first guide plate 38 which is driven in the first inclination direction inclining at the predetermined angle to the X-direction, with respect to the X-axis motor base 35 by the drive of the X-axis motor 22, and the third guide 39 which guides the first guide plate 38 in the first inclination direction with respect to the X-axis motor base 35. Besides, the second drive portion 50 includes the Y-axis motor 52, the Y-axis motor base 65 on which the Y-axis motor 52 is mounted, the second guide plate 68 which is driven in the second inclination direction inclining at the predetermined angle to the Y-direction, with respect to the Y-axis motor base 65 by the drive of the Y-axis motor 52, and the fourth guide 69 which guides the second guide plate 68 in the second inclination direction with respect to the Y-axis motor base 65. In addition, when the first guide plate 38 is driven in the first inclination direction by the X-axis motor 22, the mask holder 16 is moved in the X-direction by the action of the first guide 23, and when the second guide plate 68 is driven in the second inclination direction by the Y-axis motor 52, the mask holder 16 is moved in the Y-direction by the action of the second guide 53, so that the mask holder 16 can be moved by converting the moving distances of the first and second guide plates 38 and 68 in the first and second inclination directions, into the small moving distances of the mask holder 16 in the X- and Y-directions, respectively, whereby the X- and Y-directional movements of the mask holder 16 can be precisely controlled.

Besides, the drive directions of the X-axis motors 22 respectively disposed in the pair of first drive mechanisms 11A and 11B are in line symmetry with respect to the X-directional center line between the pair of first drive mechanisms 11A and 11B, so that the mask holder 16 can be moved in the X-direction by synchronously rotating the respective X-axis motors 22.

Further, the first drive portion 20 also includes the first Z-axis motor 21, the first Z-axial movable base 31 which can be moved in the Z-direction by the first Z-axis motor 21, and the first universal joint 34 which turnably supports the X-axis motor base 35 with respect to the first Z-axial movable base 31. The second drive portion 50 also includes the second Z-axis motor 51, the second Z-axial movable base 61 which can be moved in the Z-direction by the second Z-axis motor, and the second universal joint 64 which rotatably supports the Y-axis motor base 65 with respect to the second Z-axial movable base 61. In addition, when the first and second Z-axial movable bases 31 and 61 are tilted and driven by at least one of the first and second Z-axis motors 21 and 51, the inclination of the mask holder 16 is allowed while operating at least one of the first and second universal joints 34 and 64, and the span change amount of the mask holder 16 attributed to the tilt thereof in the top plan view among the first and second drive mechanisms 11A, 11B and 12 is absorbed by at least one of the first and second guides 23 and 53, so that the tilt drive in the integrated mechanism can be smoothly performed.

Besides, the illuminating optical system 160 includes the multi-lamp unit 161 having the plurality of light sources 273 each of which includes the high-pressure mercury-vapor lamp 271, and the reflector 272 for providing the directivity to the light generated from the high-pressure mercury-vapor lamp 271 and then emitting the light, so that the illuminating optical system 160 can be arranged in correspondence with any desired unit shape.

Besides, according to the proximity exposure method of this embodiment, in the state where the part to-be-exposed A of the conveyed work W is kept stationary in the exposure area P and where the work W and the mask M are held in proximity with the predetermined gap, the light beam of the exposure lights from the illuminating optical system 160 is projected onto the work W through the mask M, thereby to transfer the pattern of the mask M onto the work W. Here, the proximity exposure method includes the step of detecting the alignment mark Wb of the work W and the alignment mark Ma of the mask M by employing the alignment detection system 152, the step of adjusting the alignment between the work W and the mask M by driving the mask holder 16 on the horizontal plane with the mask drive mechanism 200, on the basis of the shift amount between both the alignment marks Wb and Ma detected by the alignment detection system 152, and the step of correcting the relative inclination between the work W and the mask M by tilting and driving the mask holder 16 with the mask drive mechanism 200, on the basis of the gap detected by the gap sensor 153. Accordingly, in conveying the work W and exposing the work W to the exposure lights in the state where it is stationary in the exposure area P, the exposure can be performed after the alignment adjustment and the correction made so as to uniformalize the gap between the work W and the mask M, and the pattern of the mask M can be precisely transferred by the exposure.

Besides, the proximity exposure method includes the step of calculating the positional shift amount between the work W and the mask M and the distortion amounts α and β of the work W, on the basis of the shift amount between both the alignment marks Wb and Ma detected by the alignment detection system 152, and the step of correcting the curvature of the plane mirror 166 for reflecting the light beam of the exposure lights from the light sources, on the basis of the calculated distortion amounts α and β, at a timing identical to or separate from the alignment adjustment step, wherein the alignment adjustment step adjusts the alignment between the work W and the mask M, on the basis of the calculated positional shift amount. Thus, even in a case where the work W has been distorted, the pattern of the mask M can be precisely transferred by the exposure in conformity with the shape of the part to-be-exposed A of the work W.

Besides, the curvature correction step of the plane mirror 166 includes the step of projecting the laser light L toward the plane mirror 166 from the exposure surface side with respect to the plane mirror 166, the step of imaging by the camera 193, the laser light L reflected on the reflection plate 192 through the plane mirror 166, and the step of detecting the displacement amounts S1 and S2 of the laser lights L and L′ imaged when the curvature of the plane mirror 166 has been corrected. The curvature correction step corrects the curvature so that the displacement amounts S1 and S2 may correspond to the calculated distortion amounts α and β. Thus, the curvature correction of the plane mirror 166 corresponding to the distortion amounts α and β of the work W can be reliably made while imaging the displacement amounts S1 and S2 of the laser lights L and L′.

Besides, the laser light L is projected toward the plane mirror 66 from the exposure surface side with respect to the plane mirror 66, in the optical path EL of the light beam of the exposure lights, and the reflection plate 92 is arranged in the vicinity of the integrator, so that saving in a space can be attained.

Besides, in projecting the light beam of the exposure lights from the multi-lamp unit 161 onto the mask M, the reflection plate 192 retreats from the optical path of the light beam. Thus, the reflection plate 192 does not exert influence on the light beam of the exposure lights during the actual exposure operation.

Further, the camera 193 is also arranged at the position distant from the optical path of the light beam of the exposure lights from the multi-lamp unit 161. Thus, the camera 193 does not exert influence on the light beam of the exposure lights during the actual exposure operation.

Besides, the alignment detection system includes the four alignment detection systems 152 which are respectively arranged in the vicinities of the four corners of the rectangular mask M, and the laser pointers 191 which project the laser lights L are arranged in the vicinities of the respective alignment detection systems 152, in a number identical or larger than the number of the alignment detection systems 152. More specifically, the laser pointers 191 are arranged in the vicinities of those four corners of the rectangular mask M in which the distortion amounts α and β of the work W are easily grasped. Thus, it is possible to check whether the curvature correction of the plane mirror 166 corresponding to the distortion amounts α and β more efficiently.

Besides, after at least the alignment adjustment step, the proximity exposure method includes the step of redetecting the alignment mark Wb of the work W and the alignment mark Ma of the mask M by the alignment detection system, and the step of determining whether the positional shift amount between the mask M and the work W, which is calculated at the calculation step on the basis of the shift amount between both the redetected alignment marks Wb and Ma, is within the allowable value. In a case where the positional shift amount between the mask M and the work W exceeds the allowable value at the determining step, the alignment adjustment step is executed, so that the pattern of the mask can be transferred by the exposure more precisely.

Besides, since the predetermined gap is provided between the work W and the transfer pattern depicted on the mask, the light entering the mask M is bent in correspondence with the predetermined gap by the declination angle of the plane mirror 166 attributed to the bending thereof. Hence, the pattern of the mask is projected in correspondence with the distortion of the work. Thus, even in the case where the work W has been distorted, the pattern of the mask M can be transferred by the exposure precisely in conformity with the shape of the part to-be-exposed A of the work W.

Besides, the shift amount between the center of the mask M and that of the work W and the distortion amount of the work W are calculated on the basis of the shift amounts between both the alignment marks Wb and Ma detected by the alignment detection systems 152, and the plane mirror 166 has its curvature corrected locally in such a way that the plurality of support mechanisms 171 each of which supports the peripheral part or rear surface of the plane mirror 166 are driven by the motors 175 on the basis of the calculated distortion amount of the work W. Accordingly, the curvature correction of the plane mirror 166 can be easily made by driving and controlling the motors 175 of the respective support mechanisms 171.

Besides, the mask M may include the film mask 120 which is formed with the pattern Pa, and the glass plate 122 on which the film mask 120 is bonded. In that case, the dimensional change of the film mask 120 is constrained by the glass plate 122, and the dimensional stability of the film mask 120 is improved. Thus, using the comparatively inexpensive film mask 120, the exposure of high precision can be realized by the simple configuration. Besides, the film mask 120 is bonded on the glass plate 122, and thus when a mask having new patterns thereon is to be used, the old mask may be replaced together with the glass plate 122, and the prior-art film mask need not be drawn onto the glass plate by suction, and a wrinkle or distortion does not appear in the suction. Thus, the shortening of the mask replacement time (apparatus down time) and the exposure of high precision can be realized by the simple configuration.

Besides, the glass plate 122 is held by suction on the mask holder 16 in the state where the film mask 120 is arranged on the work side with respect to the glass plate 122, and hence, the glass plate 122 is not arranged between the pattern Pa of the film mask 120 and the work W. Accordingly, the gap adjustment can be easily made, and the exposure can be performed irrespective of the thickness of the glass plate 122.

Further, the pattern Pa of the film mask 120 is formed on the surface of the film mask 120 on the side thereof stuck to the glass plate 122, so that the damage of the pattern Pa can be prevented, and the durability of the mask M can be improved.

### Second Embodiment

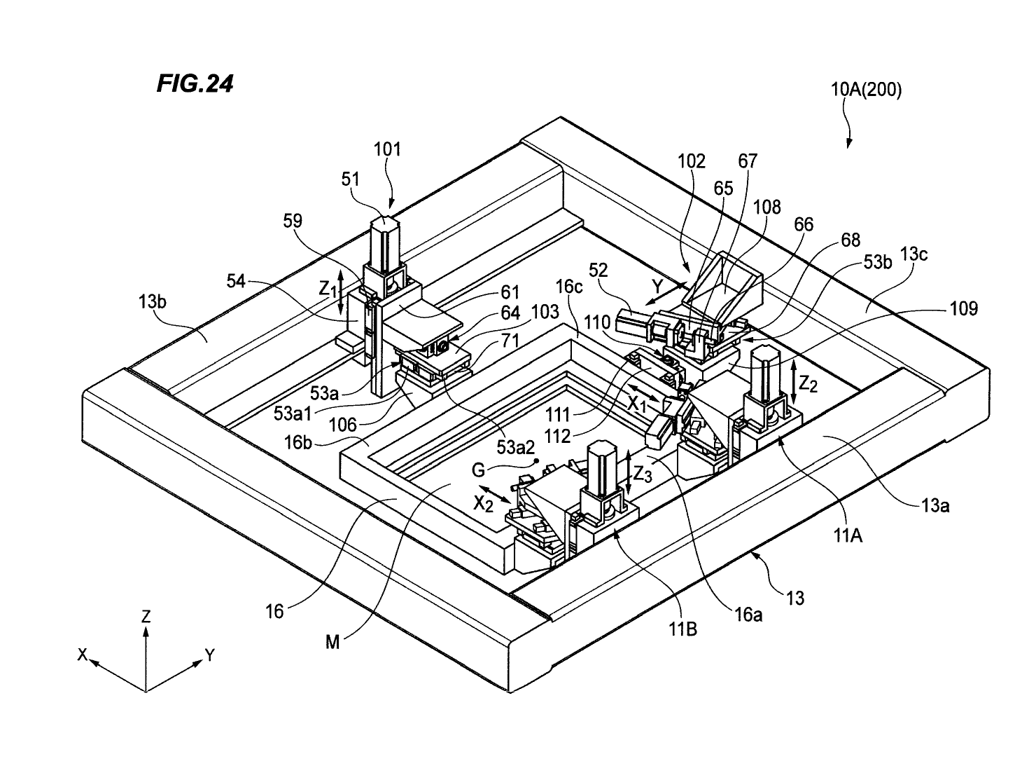

FIG. 24 is a perspective view showing a mask holding mechanism according to the second embodiment of the present invention. By the way, in this embodiment, merely a second drive mechanism differs from that of the first embodiment, and hence, the other portions shall be omitted from description by assigning signs identical or equivalent to those of the first embodiment.

The second drive mechanism 12 of the mask holding mechanism 10A in this embodiment is such that a Z-axis drive mechanism 101 capable of driving a mask holder 16 in the Z-direction, and a Y-axis drive mechanism 102 capable of driving the mask holder 16 in the Y-direction, as a second drive portion, are separately configured. The Z-axis drive mechanism 101 is fixed to one side 13b of a frame 13, and supports the intermediate position of one side 16b (one side extending in the Y-direction) opposing to one side 16a of the mask holder 16 supported by first drive mechanisms 11A and 11B. Besides, the Y-axis drive mechanism 102 is fixed to one side 13c of the frame 13 while being orthogonal to one side 13b thereof. The Y-axis drive mechanism 102 supports the intermediate position of one side 16c (one side extending in the X-direction) of the mask holder supported by the first drive mechanisms 11A and 11B while being orthogonal to one side 16a thereof. Therefore, a second guide includes a linear guide 53a which is provided in the Z-axis drive mechanism 101 and which serves as a Z-axis side guide, and a linear guide 53b which is disposed in the Y-axis drive mechanism 102 and which serves as a Y-axis side guide.

The Z-axis drive mechanism 101 has a second Z-axis motor 51 fixed to a housing 54 disposed on one side 15 of the frame 13. The second Z-axis motor 51 includes a ball screw mechanism (not shown) as in the mask holding mechanism 10 of the first embodiment, and the nut of the ball screw mechanism is connected to a Z-axial movable base 61. The second Z-axial movable base 61 is connected to an X-axis base 103 to which the slider 53a1 of the linear guide 53a is attached through a cross joint 64 being a second universal joint, so that the X-axis base 103 is supported so as to be rotatable relative to the second Z-axial movable base 61.

The guide rail 53a2 of the linear guide 53a is mounted on the upper surface of a rotary base 71, and the linear guide 53a for guiding the rotary base 71 in the X-direction is configured between the X-axis base 103 and the rotary base 71. Besides, a ball-and-roller bearing (not shown) is arranged so as to allow the rotation of the mask holder 16, between the rotary base 71 and the upper surface of an L-shaped blank 106 which is extended in a horizontal direction from a mask holder 16, thereby to configure a rotary support mechanism (not shown) as in the first embodiment. Thus, when the second Z-axis motor 51 is rotated, the mask holder 16 is moved in the Z-direction. Besides, the X-directional movement of the mask holder 16 is absorbed by the linear guide 53a, while the rotation of the mask holder 16 is absorbed by the rotary support mechanism, and the tilt of the mask holder 16 is allowed by the cross joint 64.

On the other hand, in the Y-axis drive mechanism 102, a Y-axial motor base 65 is mounted on an L-shaped blank 108 which is extended toward the inner side of the frame 13 from one side 13c of the frame 13, and a Y-axis motor 52 is fixed to the Y-axial motor base 65 in a manner to incline an angle β relative to a Y-axis. A nut 67 fixed to a second guide plate 68 is in threadable engagement with the screw shaft 66 of a ball screw mechanism which is rotated and driven by the Y-axis motor 52. A Y-axial movable base 109 serving as an opposite member is arranged under the second guide plate 68 through the linear guide 53b for guiding the mask holder 16 in the X-direction. A cross joint 110 which is disposed on the side surface of the Y-axial movable base 109 and which serves as a Y-axis side universal joint is fixed to a Z-axis base 112 which is connected to one side 16c of the mask holder 16 through a linear guide 111 that serves as a guide device extending in the Z-direction.

The mask holding mechanism 10A of this embodiment has the second drive mechanism divided into the Z-axis drive mechanism 101 and the Y-axis drive mechanism 102. In the mask holding mechanism 10 of the first embodiment shown in FIG. 2, one side 16b of the mask holder 16 as extends in the Y-direction is driven in the Y-direction, whereas in the mask holding mechanism 10A of this embodiment, one side 16c of the mask holder 16 as extends in the X-direction is driven in the Y-direction. Thus, the side 16c can be driven near the X-directional center of the mask holder 16, in other words, on the extension line of the center of gravity G of the mask holder 16.

Accordingly, in case of the large mask holder 16 which is large in size and heavy in weight, when one side which is spaced from the center of gravity G of the mask holder 16 and which extends in the Y-direction is driven in the Y-direction (see FIG. 3), the mask holder 16 might be distorted (deformed into a parallelogram), whereas according to the mask holding mechanism 10A of this embodiment, the side can be driven in the Y-direction without generating any distortion in the mask holder 16. Besides, in the same manner as in the first embodiment, the pair of first drive mechanisms 11A and 11B can perform the X-, Y-, Z- and θ-directional drives and tilt drive of the mask holder with an integrated mechanism. Thus, the drive mechanism of the mask holder can be made small in size and light in weight, to enhance a responsibility.

In this case, the Y-axis drive mechanism 102 includes the Y-axis motor 52, the Y-axis motor base 65 on which the Y-axis motor 52 is mounted, the second guide plate 68 which is driven in the second inclination direction inclining the predetermined angle relative to the Y-direction, with respect to the Y-axis motor base 65 by the drive of the Y-axis motor 52, and the Y-axis side guide 53b which guides the second guide plate 68 in the second inclination direction with respect to the Y-axis motor base 65. In addition, one of the fixed part and movable part of the Y-axis side guide 53b is mounted on the second guide plate 68, the other of the fixed part and movable part is disposed on the Y-axial movable base 109, and the Y-axis side universal joint 110 and the guide device 111 extending in the Z-direction is arranged between the Y-axial movable base 109 and the mask holder 16.

Besides, the Z-axis drive mechanism 101 includes the second Z-axis motor 51, the second Z-axial movable base 61 which can be moved in the Z-direction by the second Z-axis motor 51, the second universal joint 64 which supports the X-axis base 103 with one of the fixed part and movable part of the Z-axis side guide 53a mounted thereon, so as to be rotatable relative to the second Z-axial movable base 61, and the rotary support mechanism which supports the rotary base 71 with the other of the fixed part and movable part of the Z-axis side guide 53a mounted thereon, so as to be rotatable relative to the mask holder 16. The other configuration and operation are the same as those of the mask holding mechanism 10 of the first embodiment.

### Third Embodiment

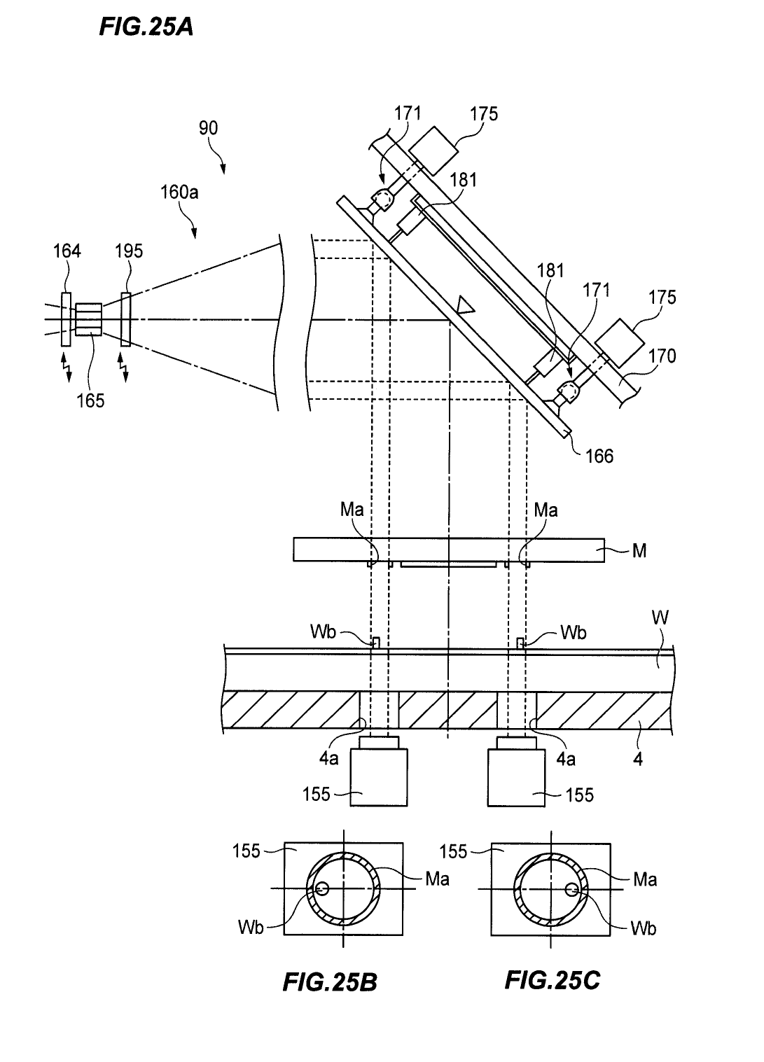

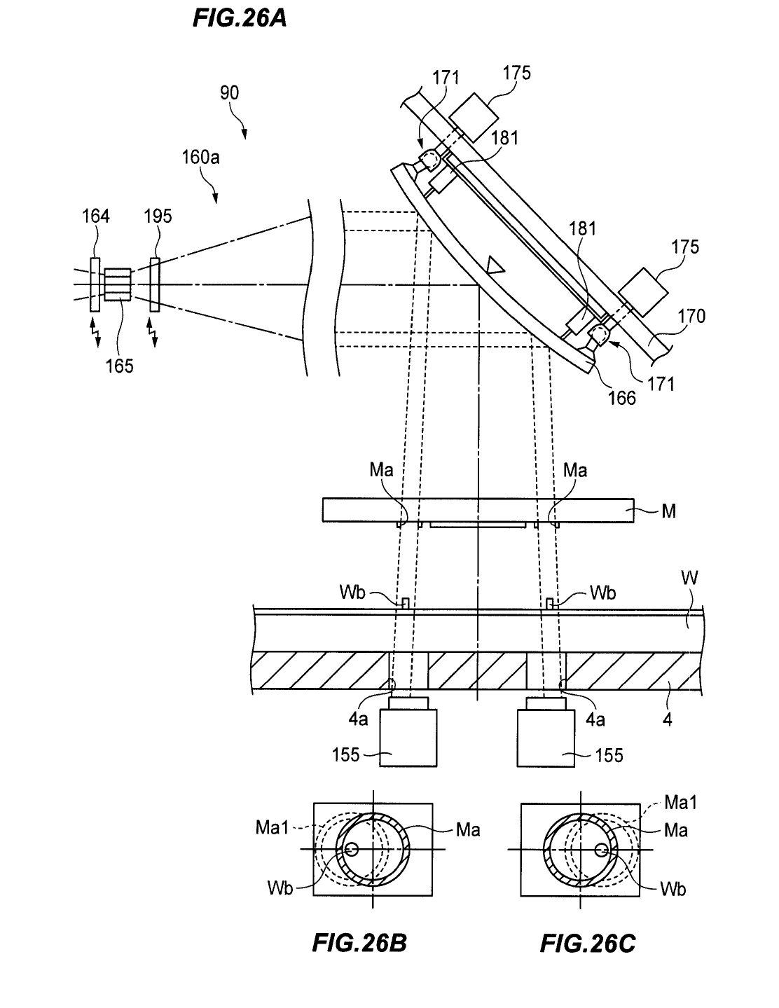

Next, a proximity exposure apparatus which exposes one side of a work with exposure light, according to the third embodiment, will be described with reference to FIGS. 25 and 26. In this embodiment, the curvature correction of a plane mirror 166 is made without disposing a curvature-correction-amount detection system 190. Incidentally, identical signs will be assigned to identical or equivalent portions in the first embodiment, and they shall be omitted from description or simplified in description.

Also in the proximity exposure apparatus of this embodiment, the exposure is performed in a state where the conveyed work W is drawn by suction to the work chuck 4 of a work table 5. Besides, in an illuminating optical system 160a, a band-pass filter 195 adapted to transmit a wavelength region to which a resist is not sensitive is disposed in a manner to capable of advancing and retreating onto an optical path.

Further, an alignment detection system 152 in this embodiment is fixed under the work chuck 4, and CCD cameras 155 image alignment marks Ma on a mask side, under the penetrating holes 4a of the work chuck 4 as are formed under the alignment marks. By the way, in a case where the work chuck 4 is of glass, the alignment marks Ma can be imaged by the CCD cameras 155 without forming the penetrating holes 4a.

Besides, each of the alignment marks Ma of the mask side in this embodiment is formed in an annular shape.

In the proximity exposure apparatus thus configured, the exposure is performed by the same steps as in the flow chart shown in FIG. 19, in the first embodiment, except the laser light imaging at the step S5.

The CCD cameras 155 can receive lights reflected by the plane mirror 166, in the wavelength region to which the resist is not sensitive, in such a way that a shutter unit 164 is opened after the band-pass filter 195 has been moved into the optical path. Therefore, after the correction by the mask drive mechanism 200, the CCD cameras 155 image the alignment marks Wb of the work W and the alignment marks Ma of each mask M as shown in FIG. 25. After the bending correction of the plane mirror 166, the CCD cameras 155 image the shades Ma1 of the alignment marks Ma of the mask side projected on the work W, as shown in FIG. 26. Here, the alignment marks Ma of the mask side are formed in the annular shape, and hence, the shades Ma1 can be prevented from being hidden by the alignment marks Ma.

In this embodiment, therefore, at the step S3 after the correction, the positional shift amount between the center of the mask M and that of the work W and the redetected offset amount between the alignment mark Wb of the work W and the shade Ma1 of the alignment mark Ma of the mask side are calculated so as to determine whether the positional shift amount between the center of the mask M and that of the work W is within an allowable value, and whether the offset amount is within an allowable value.

Besides, in a case where the positional shift amount between the mask M and the work W exceeds the allowable value, an alignment adjustment step is performed (step S4), and in a case where the offset amount exceeds the allowable value, the curvature correction step of the plane mirror 166 is performed on the basis of the offset amount (step S5).

In this way, the steps S2 to S5 in FIG. 19 are iteratively performed until the positional shift amount between the center of the mask M and that of the work W, and the offset amount become within the allowable values, respectively, and the exposure method proceeds to an exposure step (step S6) when both the amounts have become within the allowable values.

Also in this embodiment, accordingly, even in a case where the work W has been distorted, the pattern of the mask M can be transferred by the exposure precisely in conformity with the shape of the part to-be-exposed A of the work W. Besides, the redetection step further detects the shade Ma1 of the alignment mark Ma of the mask side projected on the work W by a light beam from the plane mirror 166 whose curvature has been corrected, the calculation step calculates the offset amount between the redetected alignment mark Wb of the work W and the shade Ma1 of the alignment mark Ma of the mask side, the determining step determines whether the offset amount is within the allowable value. In a case where the offset amount exceeds the allowable value at the determining step, the curvature correction step of the plane mirror 166 is performed on the basis of the offset amount, so that the transfer can be performed by the exposure more precisely.

### Fourth Embodiment

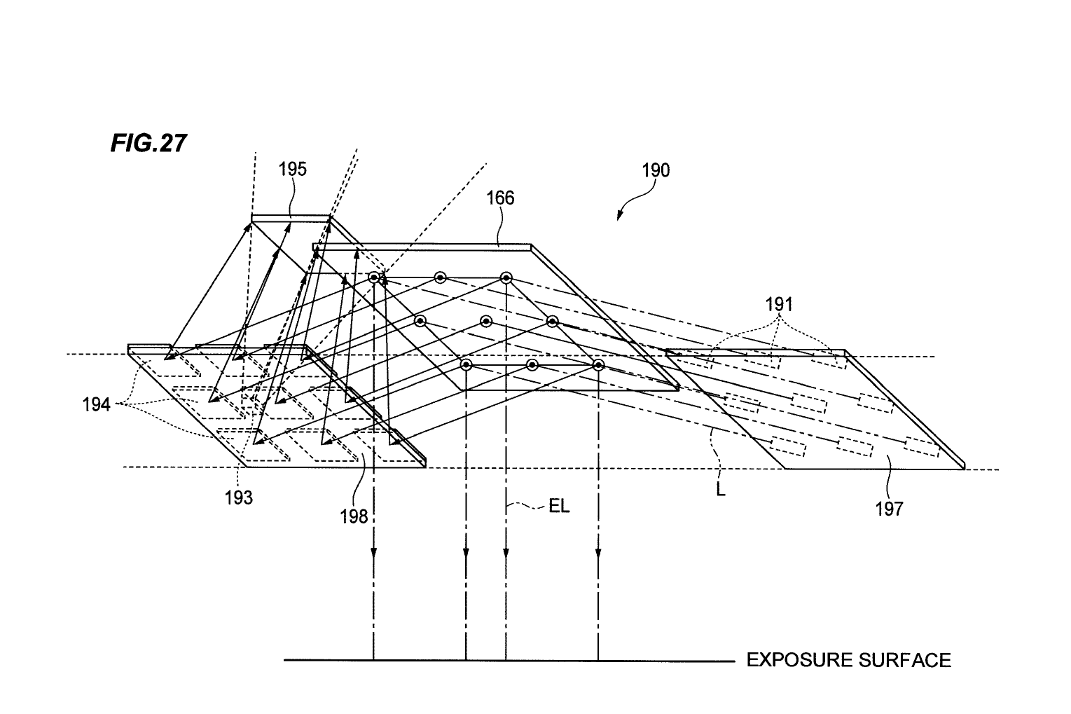

FIG. 27 is a view showing a curvature-correction-amount detection system 190 according to the fourth embodiment of the present invention. This curvature-correction-amount detection system 190 includes a plurality of laser pointers 191 (laser light sources) which can be turned ON/OFF and which project laser lights L, respectively, a reflection plate 195 which is fixedly arranged and on which the laser lights L reflected by a plane mirror 166 are projected, a light collecting mirror group 196 consisting of a plurality of mirrors 194 which are respectively disposed in correspondence with the plurality of laser pointers 191 and which reflect the laser lights L reflected by the plane mirror 166, toward the reflection plate 195, respectively, and a camera 193 (an imaging device) which images the laser lights L reflected on the reflection plate 195, through the plane mirror 166 and the light collecting mirror group 196.

The plurality of laser pointers 191 are respectively installed on a laser installing frame 197 which is fixedly arranged so as to become substantially parallel to the plane mirror 166, and they project the laser lights L toward the plane mirror 166 from the side of an exposure surface with respect to the plane mirror 166, with an angle outside the optical path EL of the light beam of exposure lights. Also, in the light collecting mirror group 196, the individual mirrors 194 are respectively installed on a mirror mounting frame 198 which is fixedly arranged on the same plane as that of the laser installing frame 197 so as to become substantially parallel to the plane mirror 166. In addition, each of the mirrors 194 has adjustment mechanisms (not shown) which are respectively driven to rotate round two axes orthogonal on a plane, in other words, which have two degrees of freedom in rotary directions. Thus, the senses of the individual mirrors 194 may be adjustable to condense the laser lights L onto the reflection plate 195 which is smaller than the light collecting mirror group 196. Besides, the camera 193 is mounted in a space which does not interfere with the individual mirrors 194 near the center of the mirror mounting frame 198.

Accordingly, also in the curvature correction detection system 190 of the fourth embodiment, the displacement amounts of the plane mirror 166 before a curvature correction and after the curvature correction can be detected by the camera 193. Especially, in this curvature correction detection system 190, the laser pointers 191, the condensed mirror group 196 and the reflection plate 195 are fixedly arranged, respectively, so that the detections of good reproducibility become possible. Besides, since this curvature correction detection system 190 is arranged independently of an alignment detection system 152, a curvature correction step can be performed irrespective of the position of the alignment detection system 152.

Incidentally, the laser installing frame 197 is not restricted to the arrangement which is substantially parallel to the plane mirror 166, as long as it permits the individual laser pointers 191 to project the laser lights onto the plane mirror 166 with the identical angle. Besides, the mirror mounting frame 198, the reflection plate 195 and the camera 193 can also be arranged at any desired positions capable of realizing their functions.

### Fifth Embodiment

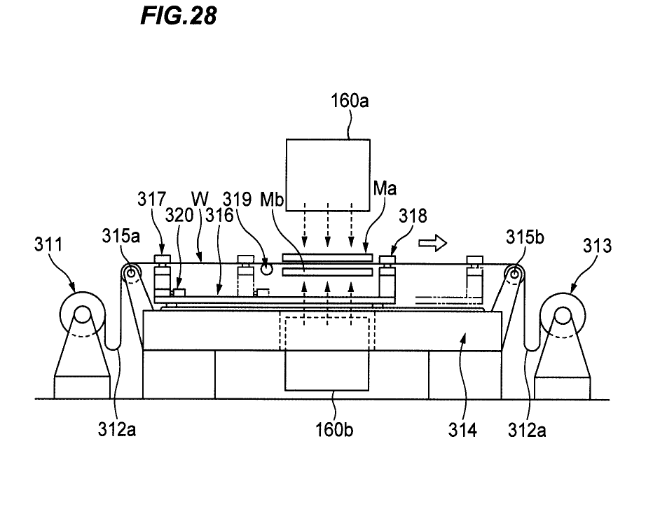

First, a contact both-sided exposure apparatus in the fifth embodiment will be described with reference to FIG. 28. In the figure, numeral 311 designates a delivery device which serves to deliver a hoop material such as work W by tact feed in a horizontal direction, while numeral 313 designates a take-up device which serves to take up the work W subjected to exposure and which is arranged on the downstream side of an exposure position P.

A trestle 314 is disposed along the conveyance direction of the work W, between the delivery device 311 and the take-up device 313, and support rolls 315a and 315b serving as work supports which support the work W substantially in the horizontal direction on the side of the delivery device 311 and the side of the take-up device 313, respectively, are mounted on both the end parts of the trestle 314 in the lengthwise direction thereof.

Besides, an indexer table 316 is disposed on the trestle 314 so as to be slidable along the conveyance direction of the work W, and a first indexer 317 is attached to the end part of the indexer table 316 on the upstream side of the exposure position P, so as to be movable in the conveyance direction of the work W, while a second indexer 318 is attached to the end part on the downstream side.

The second indexer 318 is arranged in the vicinity of the downstream side of the exposure position P, the first indexer 317 is arranged at a position spaced by the stroke +α of the indexer table 316 on the upstream side of the exposure position P, and a support roll 319 for making the flexure of the work W as small as possible is disposed in the vicinity of the upstream side of the exposure position P, so as not to interfere with the first indexer 317. Incidentally, the magnitude of the stroke is set to be, at least, the width of parts to-be-exposed in the feed direction of the work, but it should preferably be a magnitude nearly equal to the width to the utmost, in order to enhance the available percentage of the material.

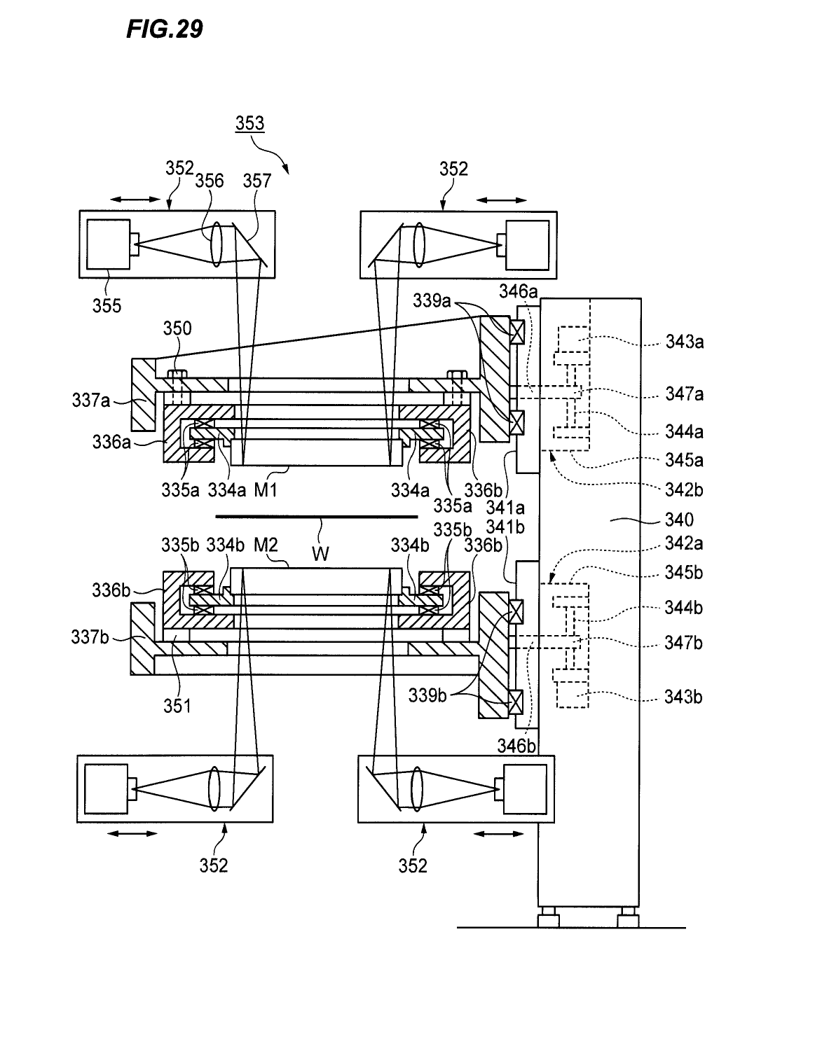

The respective indexers 317 and 318 are arranged in a manner to be spaced from each other at the smallest possible interval, while meeting the condition that the second indexer 318 at the time when the indexer table 316 lies at the leftmost position in FIG. 28 does not interfere with a mask support mechanism 353 in FIG. 29 for supporting a front mask M1 and a rear mask M2, and the condition that the first indexer 317 (indicated by two-dot chain lines) at the time when the indexer table 316 lies at the rightmost position in FIG. 28 does not interfere with the support roll 319. The work W is clamped (by employing, for example, an air cylinder) after exposure, and the indexer table 316 is fed onto the downstream side in a predetermined feed amount, thereby to convey the work W in the same direction, and to arrange new parts to-be-exposed at the exposure position P.

In addition, after the work W has been conveyed, the clamps of the work W by the respective indexers 317 and 318 are released after the completions of alignment, mask contact, etc., and the indexer table 316 is reset to its original position. In this embodiment, accordingly, the work W in an exposure area opposing to the masks M1 and M2 is supported by the respective indexers 317 and 318 during the conveyance, and it is supported by the front and rear masks M1 and M2 during the exposure.

The delivery of the work W by the delivery device 311 and the take-up of the work W by the take-up device 313 are performed in accordance with the feed amount of the work W by the respective indexers 317 and 318. Incidentally, sign 312a denotes those buffer parts of the work feed which are set on the side of the delivery device 311 and the side of the take-up device 313.

Besides, on the side of the indexer table 316 close to the first indexer 317, a cylinder device 320 is disposed which pushes the first indexer 317 onto the upstream side, thereby to impart a back tension to the work W between the respective indexers 317 and 318 which are fed to the exposure position P.

More specifically, the body (housing) of the cylinder device 320 is fixed on the indexer table 316, the expansion rod of the cylinder device 320 protrudes from the left end of the body in FIG. 28, and the distal end thereof is fixed to the indexer 317.

Here, the operations of clamping the work and imparting the back tension to the work will be described.

First, as indicated by solid lines in FIG. 28, in a state where the indexer table 316 has been reset to its original position, the work W is clamped by the clamp portions of the respective indexers 317 and 318. On this occasion, the support roll 319 supports the work W from below near the middle between the indexers 317 and 318, whereby the flexure of the work W between the respective indexers 317 and 318 is suppressed to a small amount.

Subsequently, the cylinder device 320 is actuated, whereby the indexer 317 is pressed leftwards in FIG. 28 with a predetermined force. Thus, the flexural amount of the work W between the respective indexers 317 and 318 can be suppressed to a still smaller amount.

The pressing force based on the cylinder device 320 is set at the minimum amount required for suppressing the flexure of the work W due to the weight thereof as stated above, and any excessive force is prevented from acting on the work W. The clamp and the back tension impartation are completed as described above.

As shown in FIG. 29, there are disposed mask holders which hold the front mask M1 and the rear mask M2 each having a predetermined transfer pattern, at the front and rear surfaces of the parts to-be-exposed of the work W at the exposure position P, and the mask support mechanism 353 which serves as the feed mechanism. The mask support mechanism 353 includes mask adjustment bases 334a and 334b, plain bearings 335a and 335b, mask bases 336a and 336b, and an alignment mechanism 349 which is provided in the mask bases 336a and 336b. The front mask M1 and the rear mask M2 are detachably attached to the mask adjustment bases 334a and 334b through suction by evacuation. In addition, the mask adjustment bases 334a and 334b are supported on the mask bases 336a and 336b through the plain bearings 335a and 335b so as to be minutely movable in the X-axial direction, the Y-axial direction and the θ-direction (rotary direction within an X-Y plane) for the purpose of performing the alignment between the masks M1 and M2.

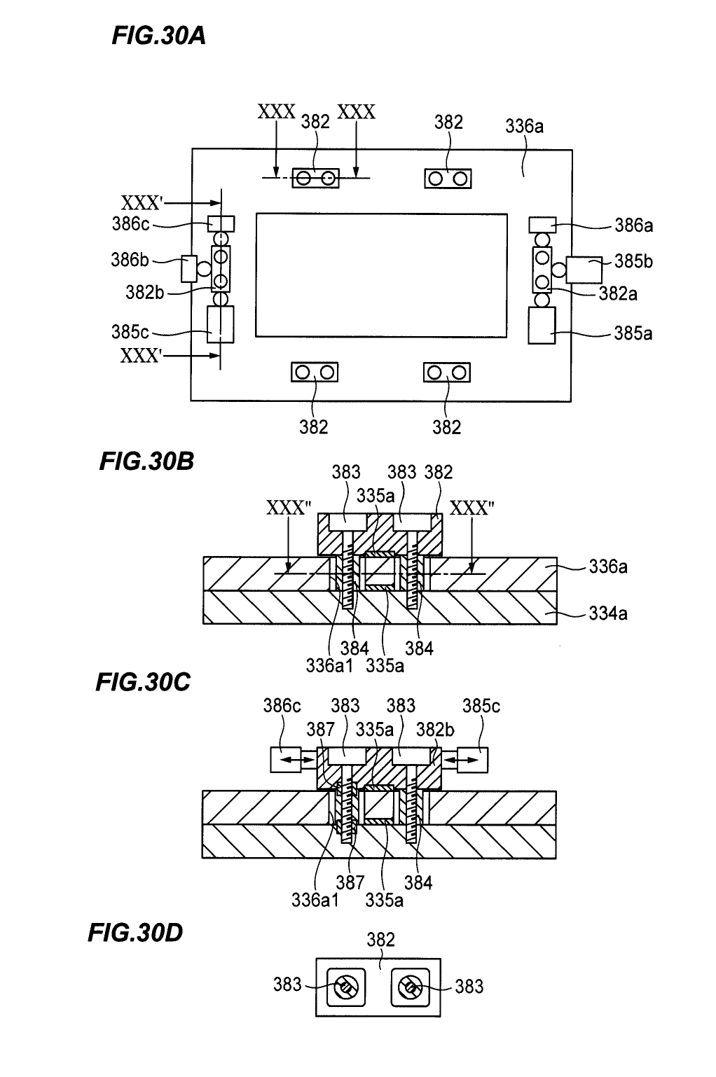

Concretely, as shown in FIG. 30, the mask adjustment base 334a and a plurality of tarkite support members 382 are mounted on the mask base 336a by a plurality of bolts 383 in a manner to hold this mask base 336a therebetween. The mask base 336a is formed with insertion holes 336a1 into each of which the bolt 383 is inserted with a clearance, and a collar 384 which is a factor of the height between the tarkite support member 382 and the mask adjustment base 334a is arranged around the bolt 383 in the insertion hole 336a1. Tarkite members 335a which serve as plain bearings are respectively mounted on the surface of the tarkite support member 382 opposing to the mask base 336a and the surface of the mask base 336a opposing to the mask adjustment base 334a. Thus, the mask adjustment base 334a is supported so as to be minutely movable in the X-axial direction, the Y-axial direction and the θ-axial direction (rotary direction within the X-Y plane) with respect to the mask base 336a. Besides, of the two tarkite support members 382a and 382b which oppose in the X-axial direction through the opening of the mask base 336a, one tarkite support member 382a is provided as the alignment mechanism 349 with a drive unit 385a which drives the mask adjustment base in the Y-axial direction and a drive unit 385b which drives the mask adjustment base in the X-axial direction, and a pressurization unit 386a which imparts a predetermined previous pressure to the tarkite support member 382a, and the other tarkite support member 382b is provided with a drive unit 385c which drives the mask adjustment base in the Y-axial direction, and pressurization units 386b and 386c each of which imparts a predetermined previous pressure to the tarkite support member 382b. Further, around one bolt 383 of each of the tarkite support members 382a and 382b, other collars 387 are respectively interposed between the tarkite support member 382a or 382b and the collar 384 and between the mask adjustment base 334a and the collar 384. Accordingly, the mask adjustment base 334a is minutely movable in the X-axial direction by driving the drive unit 385b, the mask adjustment base 334a is minutely movable in the Y-axial direction by synchronously driving the drive units 385a and 385c, and the mask adjustment base 334a is minutely movable in the θ-direction by relatively moving the drive units 385a and 385c in the Y-axial direction. Besides, the tarkite support members 382a and 382b which are pressed by the drive units 385a, 385b and 385c are provided with the other collars 387, so that the shakes between the tarkite support members 382a and 382b and the mask adjustment base 334a and the collars 384 are prevented, and an iterative responsibility is enhanced. Incidentally, the mask support 353 which supports the rear mask M2 is similarly configured.

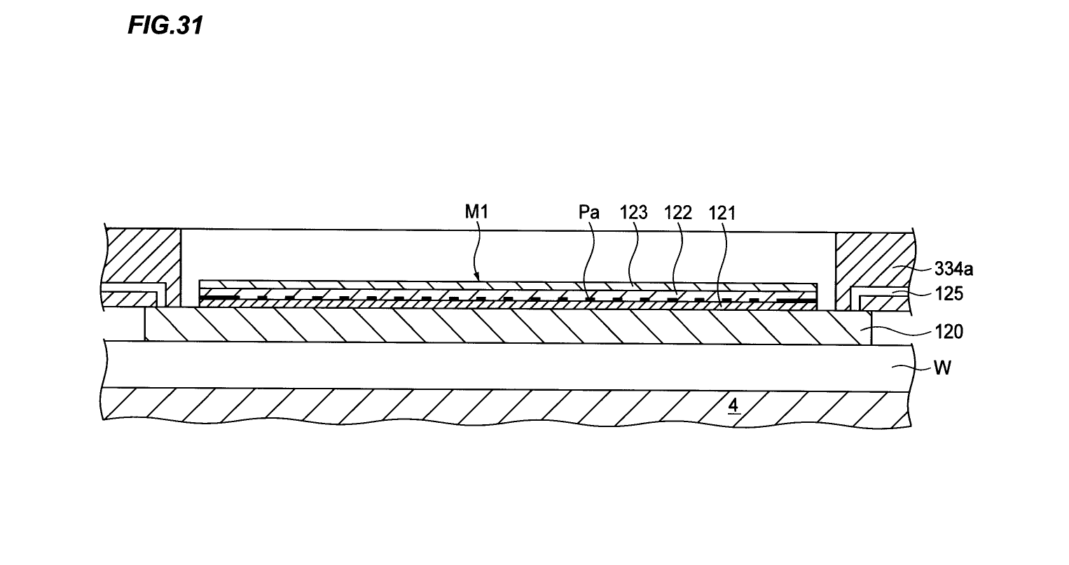

As shown in FIG. 31, the front mask M1 further includes a film mask 120 which is formed with a pattern Pa, a glass plate (transparent medium) 122 to which the film mask 120 is bonded through a resin layer 121, and a hard coat layer 123 which covers the surface of the film mask 120 opposite to the surface thereof stuck to the glass plate 122.

The glass plate 122 is drawn by suction through a pump (not shown) from a suction port 125 formed in the mask adjustment base 334a, in a state where the film mask 120 is arranged on a side opposite to the work W with respect to the glass plate 122, in other words, thereby to be held on the mask adjustment base 334a by suction. For this purpose, the film mask 120 is formed smaller than the glass plate 122 so that the marginal part of the glass plate 122 may be exposed as a suction surface. Incidentally, the rear mask M2 has a similar configuration, and is held on the mask adjustment base 334b by suction.

The mask bases 336a and 336b are respectively secured to Z-axis frames 337a and 337b. Incidentally, the mask adjustment bases 334a and 334b, the mask bases 336a and 336b, and the Z-axis frames 337a and 337b are provided with holes, and projection lights from illuminating optical systems 160a and 160b can be projected onto the front and rear masks M1 and M2. Also, the illuminating optical systems 160a and 160b are configured so as to be movable in the Z-axial direction.

The bottom parts of the Z-axis frames 337a and 337b are respectively supported by Z-axis stages 341a and 341b fixed on a both-sided exposure portion base 340, through Z-axial direct-acting bearings 339a and 339b, and the Z-axis frames 337a and 337b are respectively configured so as to be movable in the Z-axial direction on the Z-axis stages 341a and 341b, by the drives of Z-axis drive portions 342a and 342b. More specifically, each of the Z-axis drive portions 342a and 342b includes Z-axis drive motors 343a and 343b, ball screws 344a and 344b which are joined to the rotary shafts of the Z-axis drive motors 343a and 343b, columns 345a and 345b which support the ball screws 344a and 344b, drive joints 346a and 346b which are mounted on the Z-axis frames 337a and 337b, and nuts 347a and 347b which are embedded in the drive joints 346a and 346b and which are in threadable engagement with the ball screws 344a and 344b.

Under such a configuration, when the ball screws 344a and 344b are respectively rotated in interlocking with the rotations of the Z-axial drive motors 343a and 343b, the Z-axis frames 337a and 337b are respectively moved in the Z-axial direction together with the drive joints 346a and 346b, by the actions of the ball screws 344a and 344b and the nuts 347a and 347b, and the masks M1 and M2 are respectively brought into contact with both the sides of the work W.

Each of the front and rear Z-axis frames 337a and 337b is furnished with positioning adjustment screws 350 or deformation amount absorbing cushions 351 which are in the number of four and which serve as support members, and each of the mask bases 336a and 336b is fixed in a state where these constituents are interposed. By the way, in FIG. 28, for the sake of convenience, the positioning adjustment screws 350 are shown on the front side, and the deformation amount absorbing cushions 351 are shown on the rear side. The positioning adjustment screws 350 or the deformation amount absorbing cushions 351 are utilized for eliminating the torsions of the front and rear masks 321 and 322 caused by those torsions of the front and rear Z-axis frames 337a and 337b which have appeared at fabrication or at assemblage. The deformation amount absorbing cushions 351 are respectively fabricated to desired thicknesses beforehand in consideration of the fabrication errors and deformations of the Z-axis frames 337a and 337b, and the positioning adjustment screws 350 can adjust the intervals between the Z-axis frames 337a and 337b and the mask bases 336a and 336b by the advance and retreat adjustments thereof.

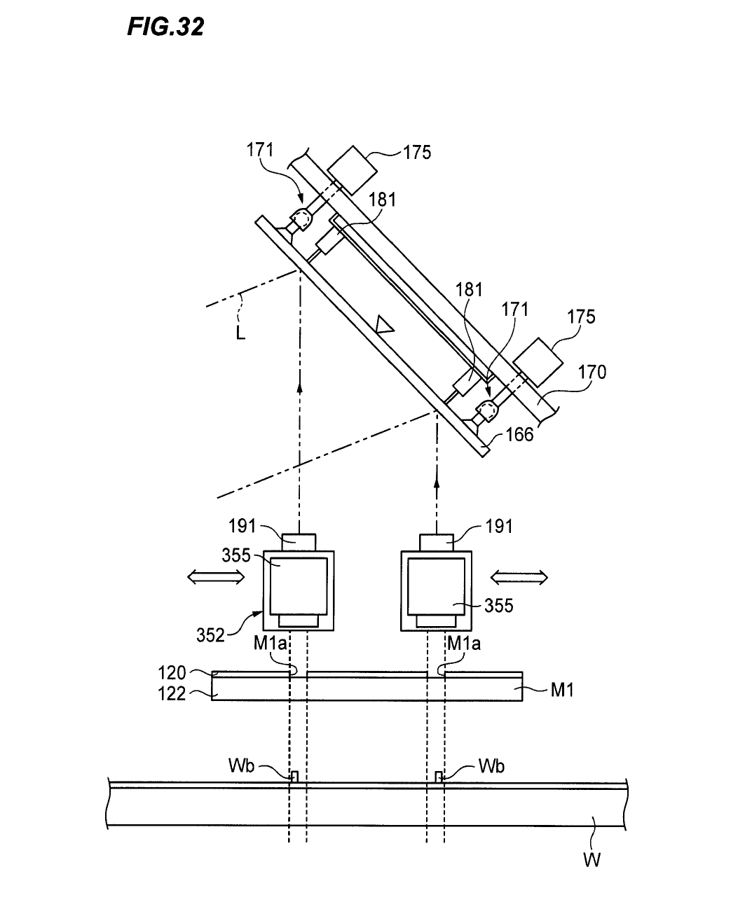

Further, as shown in FIG. 29, a plurality of alignment detection systems 352 (in this embodiment, four in total, in the vicinities of the four corners of each rectangular mask) which can be respectively advanced to and retracted from positions where the alignment marks of the mask sides can be visually recognized, are disposed on the sides opposite to the work W with respect to the masks M1 and M2. Each of the alignment systems 352 includes a CCD camera 355, an objective lens 356, a mirror 357 and projection means (not shown), and the alignment marks M1a and M2a (only the mark M1a is shown in FIG. 32) of the mask sides and the alignment mark Wb of the work side are imaged by the CCD camera 355. Incidentally, the respective alignment detection systems 352 which are located on the positions where the alignment marks of the mask sides can be visually recognized, are moved in synchronism with the mask adjustment bases 334a and 334b so as to image the alignment marks M1a and M2a of the mask sides from above.

Thus, the alignment adjustments of the front and rear masks M1 and M2 are made by the alignment mechanism 349 while the corresponding alignment marks M1a and M2a formed in the front and rear masks M1 and M2, and the alignment mark Wb of the work W are being imaged and detected by the alignment detection systems 352. Incidentally, the alignment between the front and rear masks M1 and M2 may be performed by driving and controlling the alignment mechanism 349 so that the alignment marks M1a and M2a of the respective masks M1 and M2 may coincide.

Besides, as shown in FIG. 32, also each of the illuminating optical systems 160a and 160b of this embodiment includes the plurality of support mechanisms 171 and motors 175 in the first embodiment and is configured so as to correct the curvature of the plane mirror 166. Besides, as in the first embodiment, there is disposed the curvature-correction-amount detection system 190 for determining whether the curvature correction of the plane mirror 166 corresponding to the distortion amount of the work W has been made, when the curvature of the plane mirror 166 has been corrected.

Accordingly, this embodiment includes the step of detecting the alignment mark Wb of the work W and the alignment marks M1a and M2a of the masks M1 and M2 by the alignment cameras (alignment detection systems) 352, the step of calculating the positional shift amounts between the work W and the masks M1 and M2 and the distortion amounts α and β of the work W, on the basis of the shift amounts between both the alignment marks Wb and M1a and M2a detected by the alignment cameras 352, the step of adjusting the alignments between the work W and the masks M1 and M2, on the basis of the calculated positional shift amounts, and the step of correcting the curvature of the plane mirror 166 for reflecting the light beam of the exposure lights from the light sources, on the basis of the calculated distortion amounts α and β, at a timing identical to or separate from the alignment adjustment step. Thus, even in a case where the work W has been distorted, the patterns of the masks M1 and M2 can be precisely transferred by the exposure in conformity with the shape of the area to-be-exposed A of the work W.

Besides, in this embodiment, in a case where the positional shift amounts and the distortion amounts computed at the step S3 in FIG. 19 are within the allowable values, the exposure method proceeds to the step S6, and the glass plates 122 of the respective masks M1 and M2 are brought into contact with the front and rear surfaces of the work W. In addition, the exposure lights are projected from the illuminating optical systems 160a and 160b respectively arranged outside the individual masks M1 and M2, toward the respective masks M1 and M2, through the glass plates 122 which provide the predetermined gaps between the masks M1 and M2 and the work W, whereby the exposure lights are projected onto the area to-be-exposed A of the work W (as, for example, the ground patterns) through the glass plates 122. Thus, the patterns of the respective masks M1 and M2 are transferred by the exposure onto the front and rear surfaces of the work W in the state where they coincide with the shape of the area to-be-exposed A of the work W. Incidentally, during the exposure, the work W disposed in the exposure position P is held by the masks M1 and M2, so that the clamps of the work W by the respective indexers 317 and 318 and the tension impartation to the work W by the cylinder device 320 are released.

After the exposure transfer has been performed, the indexer table 316 is fed onto the downstream side with the predetermined feed amount in the state where the work W is clamped by the respective indexers 317 and 318 stated above, thereby to convey the work W in the same direction and to arrange the new parts to-be-exposed at the exposure position P (step S7). After the conveyance, the clamps of the work W by the respective indexers 317 and 318 are released, and the indexer table 316 is reset to the original position. Thereafter, the work W fed to the exposure position P is clamped by the respective indexers 317 and 318 so as to decrease the shift amounts of the work W, the back tension is given to the work W by the cylinder device 320, and a new exposure transfer is performed through the same steps.

Besides, the glass plate 122 is held on the mask adjustment base 334a by suction in the state where the film mask 120 is arranged on the side opposite to the work W with respect to the glass plate 122, and the light beam of the exposure lights from the illuminating optical systems 160a and 160b is projected onto the work W through the mask M in the state where the glass plate 122 is held in contact with the work W and where the film mask 120 and the work W are held at the predetermined gap by the glass plate 122. Thus, an exposure transfer of high resolution can be realized based on a contact exposure scheme. Besides, since the glass plate 122 is brought into contact with the work W, the tact becomes longer than that in the first embodiment, but the adjustment of the tilt becomes unnecessary, so that the apparatus is simplified, and a cost reduction can be attained. Further, the predetermined gaps are set between the work W and the masks M1 and M2, whereby the curvature of the plane mirror 166 is changed to correct the declination angle, so that the patterns of the masks 321 and 322 can be precisely transferred by the exposure so as to correspond to the distortion of the work W

By the way, in a case where normal masks M1 and M2 in which glass plates are directly formed with patterns are employed instead of the masks M1 and M2 in which the film masks are arranged on the sides opposite to the work W with respect to the glass plates 122, a transparent medium 400 which can transmit the exposure lights and which can come into contact with the work W during the exposure may be attached to the lower surface of the mask M1 so as to hold the work W and the mask M1 at the predetermined gap by the transparent medium 400. Thus, the curvature of the plane mirror 166 can be changed to correct declination angle, and an exposure transfer of high resolution as in the contact exposure scheme can be realized. Incidentally, the transparent medium may be any material capable of transmitting the exposure lights, such as photomask (transparent film) or glass.

Incidentally, also in the above embodiment, the curvature correction of the plane mirror 166 is made after the alignments between the work W and the masks 21 and 22 are adjusted, but the shortening of a tact time may be attained by simultaneously performing the alignment adjustment and the curvature correction of the plane mirror 166. Besides, the curvature correction of the plane mirror 166 may be made by bringing the glass plates 122 and the work W into contact, after the positional shift amounts become within the allowable values by performing the alignment adjustments a plurality of times.

Besides, although the contact exposure apparatus for exposing both the sides of the work W with exposure light is shown in this embodiment, the exposure apparatus may be a contact exposure apparatus for exposing only one side of the work W to the exposure lights.

Incidentally, the present invention is not limited to the foregoing embodiment, but modifications, improvements or the like can be appropriately made.

Although the work W is hoop-shaped in this embodiment, it may be sheet-shaped (flat-plate-shaped).

The reflector for correcting the curvature in the present invention is not limited to the plane mirror 166 in the embodiment, but it may be provided as another plane mirror 163 or a collimation mirror 167, and it can be applied to any desired reflector. Besides, the curvatures of two or more of these mirrors 163, 166 and 167 may be corrected. Further, in the case of correcting the curvatures of the plurality of mirrors, the roles of the corrections can be allocated to the respective mirrors in such a manner that a contraction scale correction is made by the collimation mirror 167 and that a distortion correction is made by the plane mirror 166.

Besides, the reflection plate 192 is disposed separately from the shutter unit 164, it may be configured of the shutter unit 164 in a case where this shutter unit 164 exists on the downstream side of the integrator 165 on the optical path of the exposure lights.

Besides, the light projected onto the reflection plate as the curvature-correction-amount detection system 190 is not limited to the laser light, but a light beam smaller than that of the exposure light having the directivity may be emitted.

Further, the reflector-curvature adjustment mechanism and the curvature-correction-amount detection system are not limited to the proximity exposure apparatus and the contact exposure apparatus, but they are applicable to any exposure apparatus except a projection exposure apparatus in which a distortion correction is made by a lens system.

In addition, the detecting light source which projects the light having the directivity should preferably be arranged in the vicinity of the mask, but it may be arranged on the side of the exposure surface with respect to the reflector, and it may be arranged on the side of the work chuck with respect to the mask.

The X-direction in which the mask holder 16 is moved extends along the conveyance direction of the work in the embodiment, but it is not limited thereto, but it may be, for example, a direction orthogonal to the conveyance direction of the work.

While the present invention has been shown and described with reference to certain exemplary embodiments thereof, it will be understood by those skilled in the art that various changes in form and details may be made therein without departing from the spirit and scope of the invention as defined by the appended claims. It is aimed, therefore, to cover in the appended claim all such changes and modifications as fall within the true spirit and scope of the present invention.

What is claimed is:

1. An exposure method in which a light beam of exposure light from a light source is projected onto a work through a mask, and a pattern of the mask is transferred onto the work, the method comprising the steps of:
detecting an alignment mark of the work and an alignment mark of the mask by an alignment detection system;
calculating a positional shift amount between the mask and the work and a distortion amount of the work, based on a shift amount between both of the alignment marks detected by the alignment detection system;
adjusting an alignment between the work and the mask, based on the calculated positional shift amount; and
correcting a curvature of a reflector, which reflects the light beam of the exposure light from the light source, based on the calculated distortion amount at the same timing as the alignment adjustment step or at a different timing from the alignment adjustment step.

2. The exposure method as defined in claim 1, wherein the reflector curvature correction step comprises:
projecting light having a directivity, toward the reflector from a side of an exposure surface with respect to the reflector;
imaging the light having the directivity, which is reflected on a reflection plate through the reflector, by an imaging device; and
detecting a displacement amount of the light having the directivity, which is imaged in correcting the curvature of the reflector, wherein the curvature is corrected such that the displacement amount correspond to the calculated distortion amount.

3. The exposure method as defined in claim 2, wherein
the light having the directivity is projected toward the reflector from the side of the exposure surface with respect to the reflector, in an optical path of the light beam of the exposure light, and
the reflection plate is arranged in the vicinity of an integrator.

4. The exposure method as defined in claim 3, wherein the reflection plate is retreated from the optical path of the light beam in projecting the light beam of the exposure light from the light source onto the mask.

5. The exposure method as defined in claim 3, wherein the imaging device is arranged at a position separate from the optical path of the light beam of the exposure light from the light source.

6. The exposure method as defined in claim 3,
wherein the alignment detection system includes at least two alignment detection systems each arranged in the vicinity of an end portion of the mask, the mask being rectangular, and
wherein laser light sources each of which projects laser light as the light having the directivity are arranged in the vicinities of the respective alignment detection systems, and the number of the laser light sources is equal to or larger than the number of the alignment detection systems.

7. The exposure method as defined in claim 2, comprising:
a plurality of laser light sources each of which projects laser light as the light having the directivity; and
a light collecting mirror group comprising a plurality of mirrors each disposed to correspond to one of the laser light sources, each of the mirrors reflecting the laser light reflected by the reflector, toward the reflection plate,
wherein
the laser light sources project the laser light toward the reflector from the side of the exposure surface with respect to the reflector, outside an optical path of the light beam of the exposure light, and
the imaging device images the laser light reflected on the reflection plate, through the reflector and the light collecting mirror group.

8. The exposure method as defined in claim 1, further comprising:
redetecting the alignment mark of the work and the alignment mark of the mask by the alignment detection system after, at least, the alignment adjustment step; and
determining whether the positional shift amount between the mask and the work, which is, at the calculation step, calculated based on the redetected shift amount between both of the alignment marks is an allowable value or less,
wherein the alignment adjustment step is performed if the positional shift amount between the mask and the work exceeds the allowable value at the determination step.

9. The exposure method as defined in claim 8,
wherein the redetection step is performed after the alignment adjustment step and the reflector curvature correction step,
the redetection step comprises further detecting a shade of the alignment mark of the mask on the work, which is projected by the light beam from the reflector whose curvature is corrected,
the calculation step comprises calculating an offset amount between the redetected alignment mark of the work and the shade of the alignment mark of the mask,
the determination step comprises determining whether the offset amount is the allowable value or less; and
the reflector curvature correction step is performed based on the offset amount, if the offset amount exceeds the allowable value at the determination step.

10. The exposure method as defined in claim 1,
wherein the light beam of the exposure light is projected onto the work through the mask, such that a predetermined gap is provided between the pattern of the mask and the work.

11. The exposure method as defined in claim 10,
wherein a transparent medium is mounted on a lower surface of the mask, the transparent medium being capable of transmitting the exposure light and coming into contact with the work during the exposure.

12. The exposure method as defined in claim 10, wherein
the mask comprises: a film mask which is formed with the pattern; and a transparent medium to which the film mask is bonded, and
the transparent medium is held by suction on a mask holder such that the film mask is arranged on the work side with respect to the transparent medium.

13. The exposure method as defined in claim 12, wherein the pattern of the film mask is formed on a surface of the film mask which is bonded to the transparent medium.

14. The exposure method as defined in claim 10, wherein
the mask comprises a film mask which is formed with the pattern, and a transparent medium to which the film mask is bonded,
the transparent medium is held by suction on a mask holder such that the film mask is arranged on a side opposite to the work with respect to the transparent medium, and
the light beam of the exposure light is projected onto the work through the mask, such that the transparent medium is held in contact with the work and the film mask and the work are held at the predetermined gap by the transparent medium.

15. A work manufactured by the exposure method as defined in claim 1.

16. An exposure apparatus comprising:
a work support which supports a work;
a mask support which supports a mask;
a feed mechanism which relatively moves the work and the mask;
an illuminating optical system which comprises a light source and a reflector for reflecting a light beam of exposure light from the light source; and
an alignment detection system which detects an alignment mark of the work and an alignment mark of the mask, wherein the light beam of the exposure light from the light source is projected onto the work through the mask, so as to transfer the pattern of the mask onto the work,
wherein the illuminating optical system comprises:
a support mechanism which supports either of a peripheral edge portion of the reflector or a rear surface of the reflector; and
a support mechanism drive unit capable of moving the support mechanism,
wherein the feed mechanism relatively moves the work and the mask based on a positional shift amount between the mask and the work so as to adjust an alignment between the work and the mask, wherein the positional shift amount is calculated from a shift amount between both of the alignment marks, the shift amount being detected by the alignment detection system, and
wherein the curvature of the reflector is corrected such that the support mechanism drive unit moves the support mechanism based on a distortion amount of the work, which is calculated from the shift amount between both of the alignment marks, the shift amount being detected by the alignment detection system.

17. The exposure apparatus as defined in claim 16, further comprising:
a curvature-correction-amount detection system comprising:
a detecting light source which projects light having a directivity, toward the reflector from a side of an exposure surface with respect to the reflector;
a reflection plate onto which the light having the directivity reflected by the reflector is projected;
an imaging device which images the light having the directivity reflected on the reflection plate, through the reflector; and
a controller which detects a displacement amount of the light having the directivity which is imaged in correcting the curvature of the reflector,
wherein the curvature of the reflector is corrected by moving the support mechanism by the support mechanism drive unit such that the displacement amount of the light having the directivity, which is detected by the curvature-correction-amount detection system in correcting the curvature of the reflector, correspond to the calculated distortion amount of the work.

18. The exposure apparatus as defined in claim 16, wherein
the detecting light source projects the light having the directivity, toward the reflector from a side of an exposure surface with respect to the reflector, in an optical path of the light beam of the exposure light, and
the reflection plate is arranged to be retractable from the optical path of the light beam of the exposure light, in the vicinity of an integrator of the illuminating optical system.

19. A proximity exposure apparatus comprising:
a mask holder which holds a mask;
a conveyance mechanism which conveys a work to an exposure area opposite to the mask; and
an illuminating optical system which projects exposure light onto the work located in the exposure area, through the mask, wherein a light beam of the exposure light from the illuminating optical system is projected onto the work through the mask in a state where an exposed portion of the work conveyed to the exposure area is kept stationary and a gap between the work and the mask is close to a predetermined gap, thereby to transfer a pattern of the mask onto the work;
at least two alignment detection systems each of which detects an alignment mark of the work and an alignment mark of the mask;
at least three gap detection systems each of which detects the gap between the work and the mask located in the exposure area; and
a mask drive mechanism capable of driving the mask holder in an X-direction and a Y-direction orthogonal to each other on a horizontal plane, and a θ-direction round an axis orthogonal to the horizontal plane, and capable of tilt-driving the mask holder,
wherein the mask drive mechanism adjusts an alignment between the work and the mask by driving the mask holder on the horizontal plane based on the shift amount between both the alignment marks, which is detected by the alignment detection system, and
wherein the mask drive mechanism corrects a relative inclination between the work and the mask by tilt-driving the mask holder based on the gap detected by the gap detection system.

20. The proximity exposure apparatus as defined in claim 19, wherein the gap detection system and the alignment detection system are moved by the same detection system drive mechanism.

21. The proximity exposure apparatus as defined in claim 19,
wherein the illuminating optical system comprises:
a light source;
a reflector which reflects a light beam of exposure light from the light source;
a support mechanism which supports either a peripheral edge of the reflector or a rear surface of the reflector; and
a support mechanism drive unit capable of moving the support mechanism,
wherein the mask drive mechanism adjusts the alignment between the work and the mask by driving the mask holder on the horizontal plane, based on the positional shift amount between the mask and the work, wherein the positional shift amount is calculated from the shift amount between both of the alignment marks, the shift amount being detected by the alignment detection system, and
wherein the curvature of the reflector is corrected by moving the support mechanism by the support mechanism drive unit, based on the distortion amount of the work, wherein the distortion amount is calculated from the shift amount between both of the alignment marks, the shift amount being detected by the alignment detection system.

22. The proximity exposure apparatus as defined in claim 21, further comprising:
a curvature-correction-amount detection system comprising:
a detecting light source which projects light having a directivity, toward the reflector from a side of an exposure surface with respect to the reflector;
a reflection plate onto which the light having the directivity reflected by the reflector is projected;
an imaging device which images the light having the directivity reflected on the reflection plate, through the reflector; and
a controller which detects a displacement amount of the light having the directivity which is imaged in correcting the curvature of the reflector,
wherein the curvature of the reflector is corrected by moving the support mechanism by the support mechanism drive unit such that the displacement amount of the light having the directivity, which is detected by the curvature-correction-amount detection system in correcting the curvature of the reflector, corresponds to the calculated distortion amount of the work.

23. The proximity exposure apparatus as defined in claim 22,
wherein the detecting light source projects the light having the directivity, toward the reflector from the side of the exposure surface with respect to the reflector, in an optical path of the light beam of the exposure light, and
wherein the reflection plate is arranged to be retractable from the optical path of the light beam of the exposure light, in the vicinity of an integrator of the illuminating optical system.

24. The proximity exposure apparatus as defined in claim 22, comprising:
a plurality of laser light sources each of which projects laser light as the light having the directivity; and
a light collecting mirror group comprising a plurality of mirrors each disposed to correspond to one of the laser light sources, and each of the mirrors reflecting the laser light reflected by the reflector, toward the reflection plate,
wherein
the laser light sources project the laser lights toward the reflector from the side of the exposure surface with respect to the reflector, outside an optical path of the light beam of the exposure light, and
the imaging device images the laser lights reflected on the reflection plate, through the reflector and the light collecting mirror group.

25. The proximity exposure apparatus as defined in claim 19,
wherein the mask comprises:
a film mask which is formed with the pattern; and
a transparent medium to which the film mask is bonded; and
wherein the transparent medium is held by suction on the mask holder such that the film mask is arranged on the work side with respect to the transparent medium.

26. The proximity exposure apparatus as defined in claim 25, wherein the pattern of the film mask is formed on a surface of the film mask which is bonded to the transparent medium.

27. The proximity exposure apparatus as defined in claim 19, wherein the mask drive mechanism comprises:
a pair of first drive mechanisms each comprising:
a first drive portion capable of driving the mask holder in the X-direction and a Z-direction being a vertical direction; and
a first guide capable of guiding the mask holder in the Y-direction, and a second drive mechanism comprising:
a second drive portion capable of driving the mask holder in the Y-direction and the Z-direction; and
a second guide capable of guiding the mask holder in the X-direction, and
wherein when the mask holder is driven in the X-direction or the θ-direction by the first drive portion, a moving distance of the mask holder is absorb by the second guide,
wherein when the mask holder is moved in the Y-direction by the second drive portion, the moving distance of the mask holder is absorbed by the first guide, and
wherein when the mask holder is tilt-driven by at least one of the first and second drive portions, a span change amount between the first and second drive mechanisms in a top plan view caused by the tilt of the mask holder is absorbed by at least one of the first and second guides.

28. The proximity exposure apparatus as defined in claim 19, wherein the illuminating optical system comprises a plurality of light sources each of which includes:
the light source; and a reflection optical system which allows light emitted from the light source to have a directivity.

29. A proximity exposure method using a proximity exposure apparatus, the proximity exposure apparatus including: a mask holder that holds a mask; a conveyance mechanism that conveys a work to an exposure area opposite to the mask; an illuminating optical system that projects exposure light onto the work located in the exposure area, through the mask; at least two alignment detection systems each detecting an alignment mark of the work and an alignment mark of the mask; at least three gap detection systems each detecting a gap between the work and the mask located in the exposure area; and a mask drive mechanism capable of driving the mask holder in an X-direction and a Y-direction orthogonal to each other on a horizontal plane, and a θ-direction round an axis orthogonal to the horizontal plane, and capable of tilt-driving the mask holder, wherein a light beam of the exposure light from the illuminating optical system is projected onto the work through the mask in a state where an exposed portion of the conveyed work is kept stationary and the gap between the work and the mask is close to a predetermined gap, thereby to transfer a pattern of the mask onto the work,
the method comprising the steps of:
detecting the alignment mark of the work and the alignment mark of the mask with the alignment detection systems;
adjusting an alignment between the work and the mask by driving the mask holder on the horizontal plane by the mask drive mechanism, based on a shift amount between both of the alignment marks, the shift amount being detected by the alignment detection systems; and
correcting a relative inclination between the work and the mask by tilt-driving the mask holder by the mask drive mechanism, based on the gap detected by the gap detection system.

30. The proximity exposure method as defined in claim 29, further comprising the steps of:
calculating a positional shift amount between the mask and the work and a distortion amount of the work, on the basis of the shift amount between both the alignment marks as has been detected by the alignment detection systems; and
correcting a curvature of a reflector which reflects the light beam of the exposure light from a light source of the illuminating optical system, on the basis of the distortion amount calculated at a timing identical to or separate from the alignment adjustment step;
wherein:
the alignment adjustment step adjusts the alignment between the work and the mask, on the basis of the calculated positional shift amount.

31. The proximity exposure method as defined in claim 29, wherein the reflector curvature correction step comprises the steps of:
projecting light having a directivity, toward the reflector from a side of an exposure surface with respect to the reflector, in an optical path of the light beam of the exposure light;
imaging the light having the directivity, which is reflected on a reflection plate arranged in the vicinity of an integrator, through the reflector by an imaging device; and
detecting a displacement amount of the light having the directivity which is imaged in correcting the curvature of the reflector;
the curvature of the reflector is corrected such that the displacement amount corresponds to a calculated distortion amount.

32. A work manufactured by the proximity exposure method as defined in claim 29.
